(19) United States
(12) Patent Application Publication
(10) Pub. No.: US 2024/0371763 A1
(43) Pub. Date: Nov. 7, 2024

(54) SEMICONDUCTOR MEMORY DEVICE

(71) Applicant: Kioxia Corporation, Tokyo (JP)

(72) Inventor: Shinya Arai, Yokohama Kanagawa (JP)

(73) Assignee: Kioxia Corporation, Tokyo (JP)

(21) Appl. No.: 18/639,503

(22) Filed: Apr. 18, 2024

(30) Foreign Application Priority Data
May 1, 2023 (JP) 2023-075610

(51) Int. Cl. H01L 23/528; G11C 16/04; H01L 25/065; H10B 41/10; H10B 41/27; H10B 41/35; H10B 43/10; H10B 43/27; H10B 43/35; H10B 80/00

(52) U.S. Cl. CPC H01L 23/5283; G11C 16/0483; H01L 25/0657; H10B 41/10; H10B 41/27; H10B 41/35; H10B 43/10; H10B 43/27; H10B 43/35; H10B 80/00; H01L 2225/06524

(57) ABSTRACT

According to one embodiment, a semiconductor memory device includes a first chip and a second chip. The first chip includes a plurality of first interconnect layers stacked apart from each other in a first direction, a memory pillar extending in the first direction and passing through the plurality of first interconnect layers, a second interconnect layer electrically coupled to the memory pillar, a first electrode electrically coupled to any one of the plurality of first interconnect layers, and a second electrode electrically coupled to the second interconnect layer. The second chip includes a third electrode bonded to the first electrode, and a fourth electrode bonded to the second electrode. A length of the first electrode in the first direction is larger than a length of the second electrode in the first direction.

### CROSS-REFERENCE TO RELATED APPLICATION(S)

This application is based upon and claims the benefit of priority from Japanese Patent Application No. 2023-075610, filed May 1, 2023, the entire contents of which are incorporated herein by reference.

### FIELD

Embodiments described herein relate generally to a semiconductor memory device.

### BACKGROUND

A NAND flash memory is known as a semiconductor memory device.

### BRIEF DESCRIPTION OF THE DRAWINGS

FIG. 1 is a block diagram showing an example of an overall configuration of a semiconductor memory device according to a first embodiment.

FIG. 2 is a circuit diagram of a memory cell array included in the semiconductor memory device according to the first embodiment.

FIG. 3 is a perspective view showing an example of the bonded structure of the semiconductor memory device according to the first embodiment.

FIG. 4 is a plan view of the memory cell array included in the semiconductor memory device according to the first embodiment.

FIG. 5 is an enlarged view of the region ER shown in FIG. 4.

FIG. 6 is a cross-sectional view of the semiconductor memory device, along line IIX-IIX of FIG. 5.

FIG. 7 is a cross-sectional view of the semiconductor memory device, along line IX-IX of FIG. 5.

FIG. 8 is a cross-sectional view of a bonding pad included in the semiconductor memory device according to the first embodiment.

FIG. 9 is a cross-sectional view of the memory cell array included in the semiconductor memory device according to the first embodiment.

FIG. 10 is a cross-sectional view taken along line X-X indicated in FIG. 9.

FIG. 11 is a cross-sectional view indicating a manufacturing process of an array chip included in the semiconductor memory device according to the first embodiment.

FIG. 12 is a cross-sectional view indicating a manufacturing process of an array chip included in the semiconductor memory device according to the first embodiment.

FIG. 13 is a cross-sectional view indicating a manufacturing process of an array chip included in the semiconductor memory device according to the first embodiment.

FIG. 14 is a cross-sectional view of a manufacturing process of an array chip included in the semiconductor memory device according to the first embodiment.

FIG. 15 is a cross-sectional view indicating a manufacturing process of an array chip included in the semiconductor memory device according to the first embodiment.

FIG. 16 is a cross-sectional view indicating a manufacturing process of an array chip included in the semiconductor memory device according to the first embodiment.

FIG. 17 is a cross-sectional view indicating a manufacturing process of an array chip included in the semiconductor memory device according to the first embodiment.

FIG. 18 is a cross-sectional view indicating a manufacturing process of an array chip included in the semiconductor memory device according to the first embodiment.

FIG. 19 is a cross-sectional view indicating a manufacturing process of an array chip included in the semiconductor memory device according to the first embodiment.

FIG. 20 is a cross-sectional view indicating a manufacturing process of an array chip included in the semiconductor memory device according to the first embodiment.

FIG. 21 is a cross-sectional view of a semiconductor memory device according to a second embodiment.

FIG. 22 is a cross-sectional view indicating a manufacturing process of an array chip included in the semiconductor memory device according to the second embodiment.

FIG. 23 is a cross-sectional view indicating a manufacturing process of an array chip included in the semiconductor memory device according to the second embodiment.

FIG. 24 is a cross-sectional view indicating a manufacturing process of an array chip included in the semiconductor memory device according to the second embodiment.

FIG. 25 is a cross-sectional view indicating a manufacturing process of an array chip included in the semiconductor memory device according to the second embodiment.

FIG. 26 is a cross-sectional view of a semiconductor memory device according to a third embodiment.

FIG. 27 is a cross-sectional view of a bonding pad included in the semiconductor memory device according to the third embodiment.

FIG. 28 is a cross-sectional view indicating a manufacturing process of an array chip included in the semiconductor memory device according to the third embodiment.

FIG. 29 is a cross-sectional view indicating a manufacturing process of an array chip included in the semiconductor memory device according to the third embodiment.

FIG. 30 is a cross-sectional view indicating a manufacturing process of an array chip included in the semiconductor memory device according to the third embodiment.

FIG. 31 is a cross-sectional view indicating a manufacturing process of an array chip included in the semiconductor memory device according to the third embodiment.

FIG. 32 is a cross-sectional view indicating a manufacturing process of an array chip included in the semiconductor memory device according to the third embodiment.

FIG. 33 is a cross-sectional view indicating a manufacturing process of an array chip included in the semiconductor memory device according to the third embodiment.

### DETAILED DESCRIPTION

In general, according to one embodiment, a semiconductor memory device includes a first chip and a second chip. The first chip includes a plurality of first interconnect layers stacked apart from each other in a first direction, a memory pillar extending in the first direction and passing through the plurality of first interconnect layers, a second interconnect layer electrically coupled to the memory pillar, a first electrode electrically coupled to any one of the plurality of first interconnect layers, and a second electrode electrically coupled to the second interconnect layer. The second chip includes a third electrode bonded to the first electrode, and a fourth electrode bonded to the second electrode. A length of the first electrode in the first direction is larger than a length of the second electrode in the first direction.

Hereinafter, an embodiment is described with reference to the drawings. The description provided hereinafter uses the same reference symbol for components having approximately the same function and configuration. Duplicate descriptions may be omitted where unnecessary. The embodiments to be described below are shown as an example of a device or a method for embodying the technical idea of the embodiments. The technical ideas of the embodiments are not intended to limit the materials, shapes, structures, arrangements, etc. of the components to those described herein. Various modifications can be made to the technical ideas of the embodiments to an extent that does not deviate from the essence of the invention. The accompanying claims and their equivalents are intended to cover such forms or modifications.

### 1. First Embodiment

A semiconductor memory device according to the first embodiment is described. Hereinafter, a three-dimensionally stacked type NAND flash memory in which memory cell transistors are three-dimensionally stacked above a semiconductor substrate will be described as an example of the semiconductor memory device.

### 1.1 Configuration

### 1.1.1 Overall Configuration of Semiconductor Memory Device

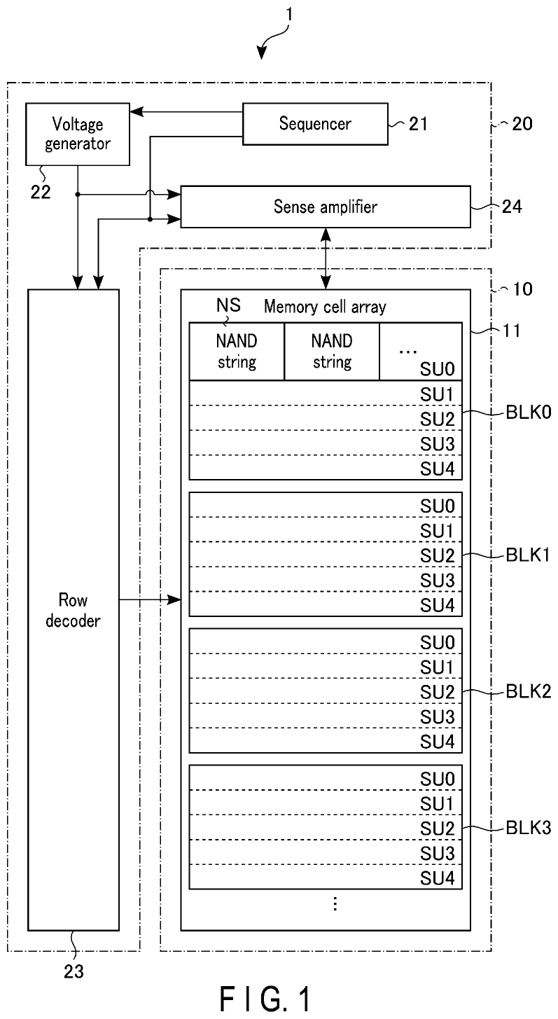

First, an example of an overall configuration of the semiconductor memory device 1 is described with reference to FIG. 1. FIG. 1 is a block diagram showing an overall configuration of the semiconductor memory device 1. In FIG. 1, some of the couplings between the constituent elements are indicated by arrows; however, the couplings between the constituent elements are not limited to those shown in FIG. 1.

The semiconductor memory device 1 is a three-dimensionally stacked-type NAND flash memory, for example. The three-dimensionally stacked-type NAND flash memory includes a plurality of non-volatile memory cell transistors that are three-dimensionally arranged on the semiconductor substrate.

As shown in FIG. 1, the semiconductor memory device 1 includes an array chip 10 and a circuit chip 20.

The array chip 10 is provided with a memory cell array including non-volatile memory cell transistors. The circuit chip 20 is provided with a circuit for controlling the array chip 10. The semiconductor memory device 1 of the present embodiment has a structure in which the array chip 10 and the circuit chip 20 are bonded (hereinafter, a “bonded structure”). Hereinafter, if the chip is not specified as the array chip 10 or the circuit chip 20, it will be simply referred to as a “chip”. More than one array chip 10 may be provided. In this case, a plurality of array chips 10 and the circuit chip 20 may be bonded in such a manner that the array chips 10 are stacked on the circuit chip 20.

The array chip 10 includes one or more memory cell arrays 11. The memory cell array 11 is an area where the non-volatile memory cell transistors (or “memory cells”) are arranged three-dimensionally. In the example of FIG. 1, the array chip 10 includes one memory cell array 11.

The circuit chip 20 includes a sequencer 21, a voltage generator 22, a row decoder 23, and a sense amplifier 24.

The sequencer 21 is a control circuit of the semiconductor memory device 1. For example, the sequencer 21 is coupled to the voltage generator 22, the row decoder 23, and the sense amplifier 24. The sequencer 21 controls the voltage generator 22, the row decoder 23, and the sense amplifier 24. The sequencer 21 controls the operation of the entire semiconductor memory device 1 based on an external controller's control. More specifically, the sequencer 21 performs a write operation, a read operation, and an erase operation, etc.

The voltage generator 22 is a circuit for generating voltages used for the write operation, the read operation, and the erase operation, etc. For example, the voltage generator 22 is coupled to the row decoder 23 and the sense amplifier 24. The voltage generator 22 supplies the generated voltages to the row decoder 23 and the sense amplifier 24, etc.

The row decoder 23 is a circuit for decoding a row address. The row address is an address signal designating an interconnect of the memory cell array 11 in the row direction. The row decoder 23 supplies voltages applied from the voltage generator 22 to the memory cell array 11 based on a decoding result of the row address.

The sense amplifier 24 is a circuit for writing and reading data. In the read operation, the sense amplifier 24 senses data that is read from the memory cell array 11. In the write operation, the sense amplifier 24 supplies voltages to the memory cell array 11 in accordance with write data.

Next, the internal configuration of the memory cell array 11 is described. The memory cell array 11 includes a plurality of blocks BLK. The block BLK is an assembly of a plurality of memory cell transistors whose data is erased in batch, for example. A plurality of memory cell transistors in a block BLK are associated with respective rows and columns. In the example of FIG. 1, the memory cell array 11 includes blocks BLK0, BLK1, BLK2, and BLK3.

The block BLK includes a plurality of string units SU. The string unit SU is a set of NAND strings that are selected in a batch in the write operation or the read operation, for example. Each NAND string includes a set of memory cell transistors coupled in series. In the example shown in FIG. 1, each block BLK includes five string units SU0 to SU4. The number of blocks BLK in the memory cell array 11 and the number of string units SU in the block BLK are discretionarily determined.

### 1.1.2 Circuit Configuration of Memory Cell Array

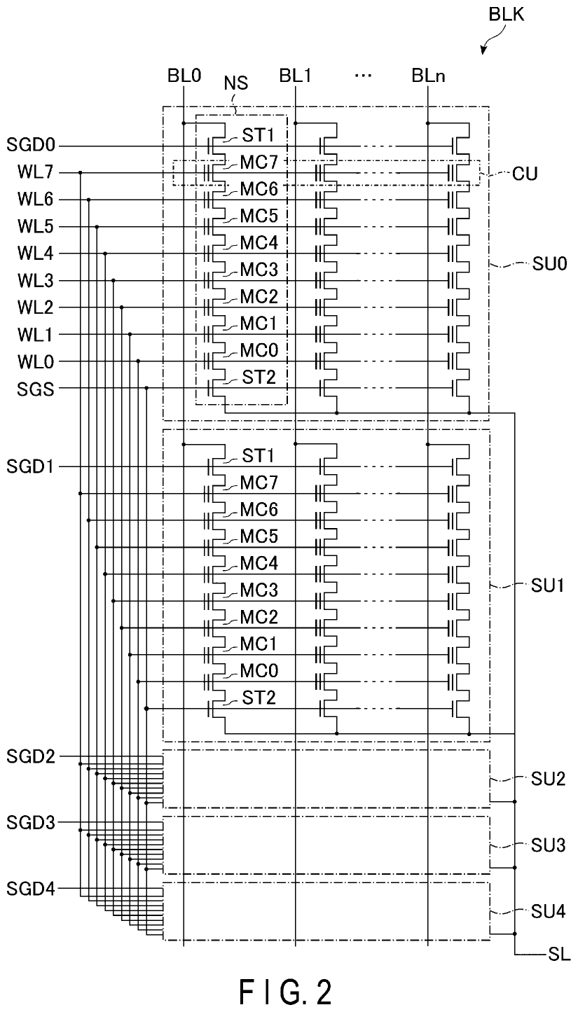

Next, an example of the circuit configuration of the memory cell array 11 is described, with reference to FIG. 2. FIG. 2 is a circuit diagram illustrating the memory cell array 11. The example of FIG. 2 shows a circuit configuration of a single block BLK.

As shown in FIG. 2, the string unit SU includes a plurality of NAND strings NS.

The NAND strings NS each include, for example, a plurality of memory cell transistors MC and select transistors ST1 and ST2. In the example of FIG. 2, the NAND string NS includes eight memory cell transistors MC0 through MC7. The number of memory cell transistors MC included in the NAND string NS is discretionarily determined.

Each memory cell transistor MC is a memory element that stores data in a non-volatile manner. Each memory cell transistor MC includes a control gate and a charge storage film. Each memory cell transistor MC may be a MONOS (metal-oxide-nitride-oxide-silicon) type or an FG (floating gate) type. A MONOS type uses an insulating layer for the charge storage film. An FG type uses a conductor for the charge storage film. Hereinafter, the case where the memory cell transistor MC is the MONOS-type will be described.

The select transistors ST1 and ST2 are a switching element. The select transistors ST1 and ST2 are used to select a string unit SU at the time of various types of processing. Furthermore, the number of select transistors ST1 and ST2 included in each NAND string NS is discretionarily determined. It suffices that at least one or more select transistor ST1 and one or more select transistors ST2 are included in each NAND string NS.

In each NAND string NS, the current paths of the select transistor ST2, the memory cell transistors MC0 through MC7, and the select transistor ST1 are coupled in series. The drain of the select transistor ST1 is coupled to a bit line BL. The source of the select transistor ST2 is coupled to a source line SL.

The control gates of memory cell transistors MC0 through MC7 in the same block BLK are respectively coupled to word lines WL0 through WL7. More specifically, for example, each block BLK includes five string units SU0 to SU4. Each string unit SU includes a plurality of memory cell transistors MC0. The control gates of the plurality of memory cell transistors MC0 in a block BLK are coupled to a single word line WL0. This coupling is the same throughout the memory cell transistors MC1 through MC7.

The gates of the plurality of the select transistors ST1 in the string unit SU are coupled in common to a single select gate line SGD. More specifically, the gates of the plurality of select transistors ST1 in the string unit SU0 are coupled in common to the select gate line SGD0. The gates of a plurality of select transistors ST1 in the string unit SU1 are coupled in common to the select gate line SGD1. The gates of a plurality of select transistors ST1 in the string unit SU2 are coupled in common to the select gate line SGD2. The gates of a plurality of select transistors ST1 in the string unit SU3 are coupled in common to the select gate line SGD3. The gates of a plurality of select transistors ST1 in the string unit SU4 are coupled in common to the select gate line SGD4.

The gates of a plurality of select transistors ST2 in a block BLK are coupled in common to the select gate line SGS. Similarly to the select gate line SGD, different select gate lines SGS are provided in respective string units SU.

The word lines WL0 through WL7, the select gate lines SGD0 through SGD4, and the select gate line SGS are coupled to the row decoder 23.

The bit line BL is coupled to a single NAND string NS in each string unit SU in each block BLK. The same column address is assigned to a plurality of NAND strings NS coupled to a single bit line BL. Each bit line BL is coupled to the sense amplifier 24.

The source line SL is shared among a plurality of blocks BLK, for example.

A group of memory cell transistors MC coupled to a common word line WL in a single string unit SU is referred to as, for example, a “cell unit CU”. For example, the write operation and the read operation are performed in a unit of cell unit CU.

### 1.1.3 Bonded Structure of Semiconductor Memory Device

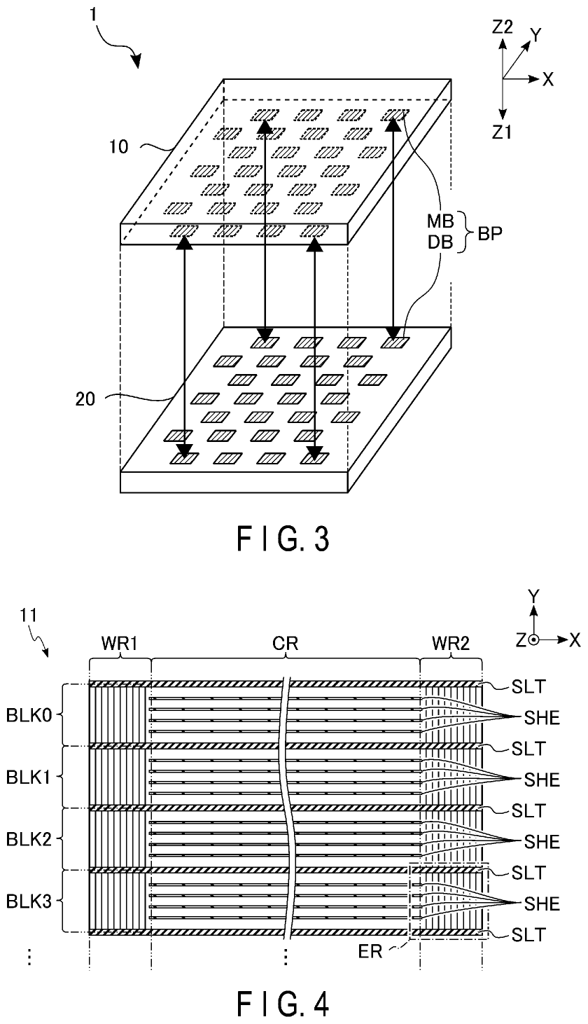

Next, a summary of the bonded structure of the semiconductor memory device 1 is described with reference to FIG. 3. FIG. 3 is a perspective view showing an example of the bonded structure of the semiconductor memory device 1.

As shown in FIG. 3, the array chip 10 includes a plurality of bonding pads MB provided on the surface facing the circuit chip 20. The circuit chip 20 includes a plurality of bonding pads DB provided on the surface facing the array chip 10 so as to face the bonding pads MB. In a bonded structure, the bonding pad MB of the array chip 10 and the bonding pad DB of the circuit chip 20 are bonded forming a single bonding pad BP. In other words, the bonding pad BP is formed by bonding the electrode (conductor) forming the bonding pad MB provided on the array chip 10 and the electrode (conductor) forming the bonding pad DB provided on the circuit chip 20.

Hereinafter, the surface in which the array chip 10 and the circuit chip 20 are bonded (hereinafter, the “bonded surface”) is defined as the XY surface. The directions perpendicular to each other on the XY plane are an X direction and a Y direction. A direction that is approximately perpendicular to the XY plane and points from the array chip 10 toward the circuit chip 20 is defined as the Z1 direction. A direction that is approximately perpendicular to the XY plane and points from the circuit chip 20 toward the array chip 10 is defined as the 22 direction. If the direction is not specified as the Z1 direction or the Z2 direction, it will be simply written as “the Z direction”.

### 1.1.4 Planar Layout of Memory Cell Array

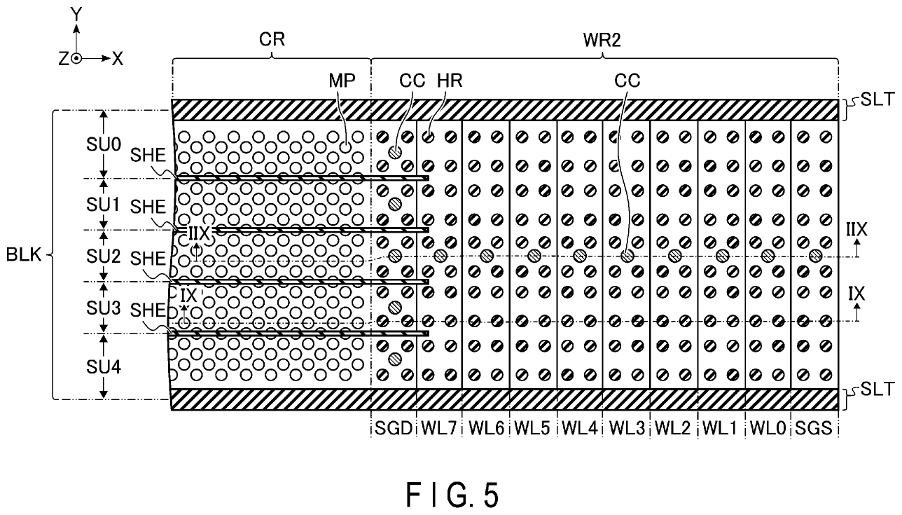

Next, an example of the planar layout of the memory cell array 11 is described, with reference to FIGS. 4 and 5. FIG. 4 is a plan view showing an example of a planar layout of the memory cell array 11. FIG. 5 is an enlarged view of the region ER shown in FIG. 4. The example of FIG. 4 shows a region corresponding to four blocks BLK0 to BLK3 included in the memory cell array 11. In the example of FIGS. 4 and 5, interlayer insulating films are omitted.

As shown in FIG. 4, the memory cell array 11 includes a WL region WR1, a cell region CR, and a WL region WR2. Hereinafter, if “WL region WR” is not specified as the WL region WR1 or the WL region WR2, it will be simply referred to as “WL region WR”.

The cell region CR is a region in which the memory cell transistors MC are provided.

The WL region WR is a region in which the word lines WL and the select gate lines SGD and SGS are coupled to the plurality of contact plugs respectively corresponding thereto. The WL regions WR1 and WR2 are provided at the X-direction ends of the cell region CR. The WL region WR may be provided within the cell region CR. In the WL region WR, the X-direction extending ends of the word lines WL and the select gate lines SGD and SGS are drawn out in a stepwise manner. Hereinafter, the area in which the word lines WL and the select gate lines SGD and SGS are drawn out in a stepwise manner will be referred to as a “terrace”. In the WL region WR, the word lines WL and the select gate lines SGD and SGS are not necessarily drawn out in a stepwise manner. Even in this case, it is possible to form a plurality of contact plugs each is electrically coupled to a target interconnect layer and not electrically coupled to other interconnect layers.

The memory cell array 11 includes a plurality of slits SLT and a plurality of slits SHE, for example.

The slits SLT extend in the X direction, and traverse the WL region WR1, the cell region CR, and the WL region WR2. The plurality of slits SLT are arranged in the Y direction. Each slit SLT has, for example, a structure into which an insulator is embedded. The slit SLT may contain a conductor coupled to a source line SL. Each slit SLT segments interconnects that are adjacent to each other via the slit SLT (e.g., the word lines WL0 to WL7 and the select gate lines SGD and SGS). In the memory cell array 11, each of the regions sectioned by the slits SLT corresponds to one block BLK.

The slit SHE extends in the X direction and traverses the cell region CR. The plurality of slits SHE are arranged in the Y direction. In the present embodiment, four slits SHE are arranged between any two slits SLT adjacent to each other in the Y direction. Each slit SHE has, for example, a structure into which an insulator is embedded. Each slit SHE divides interconnects (at least the select gate line SGD) that are adjacent to each other via that slit SHE. In the memory cell array 11, each of the regions sectioned by the slits SLT and SHE corresponds to one string unit SU.

The number of slits SHE arranged between two neighboring slits SLT can be freely designed. The number of string units SU included in each block BLK may be changed based on the number of the slits SHE arranged between adjacent slits SLT.

Next, the details of the planar structure are described.

As shown in FIG. 5, for example, in each block BLK, a plurality of interconnects that respectively function as the select gate line SGS, the word lines WL0 through WL7, and the select gate line SGD are stacked apart from each other in the Z direction. For example, the select gate line SGS, the word lines WL0 through WL7, and the select gate lines SGD extend in the X direction, and are drawn out in a stepwise manner in the WL region WR. In the example of FIG. 5, a terrace corresponding to the select gate line SGS, the word lines WL0 through WL7, the select gate line SGD, from the right side to the left side of the drawing sheet, is provided in the WL region WR2. Slits SLT are respectively provided in two side surfaces, facing in the Y direction, of the select gate line SGS, the word lines WL0 through WL7, and the select gate line SGD. The slit SLT extends in the X direction and the Z direction. The slit SLT sections the select gate line SGS, the word lines WL0 through WL7, and the select gate line SGD by block BLK. In each block BLK, the select gate line SGD is sectioned by the slit SHE in the Y direction. The slit SHE extends in the X direction. In the example of FIG. 5, the select gate line SGD is sectioned into five by four slits SHE. Each of the areas sectioned by the slits SLT and SHE corresponds to one string unit SU. In the example of FIG. 5, the sectioned areas correspond to string units SU0 through SU4, from the top to the bottom of the drawing sheet, respectively. In other words, the select gate lines SGD0 through SGD4 are arranged in the Y direction from the top to the bottom of the drawing sheet.

A plurality of memory pillars MP are provided in the cell region CR. The memory pillar MP is a pillar corresponding to a NAND string NS. The structure of the memory pillars MP will be described later in detail. Each memory pillar MP extends in the Z direction. The memory pillar MP penetrates (passes through) the select gate line SGS, the word lines WL0 through WL7, and the select gate line SGD, which are stacked in the Z direction.

In the example of FIG. 5, the plurality of memory pillars MP in the cell region CR are arranged in a staggered arrangement in the X direction. The arrangement of the memory pillars MP can be designed discretionarily. For example, the arrangement of the memory pillars MP may not be necessarily a staggered arrangement.

The WL region includes a plurality of contact plugs CC and a plurality of dummy pillars HR.

One end of the contact plug CC is coupled to a terrace of the interconnect layer of any one of the select gate line SGS, the word lines WL0 through WL7, or the select gate line SGD. The contact plug CC is not electrically coupled to the other interconnect layers. The other end of the contact plug CC is electrically coupled to the row decoder 23. In the example shown in FIG. 5, 14 contact plugs CC corresponding to the select gate line SGS, the word lines WL0 through WL7, or the select gate lines SGD0 through SGD4 are provided.

As a method of forming the word lines WL and the select gate lines SGD and SGS, there is a method of forming interconnect layers by replacing sacrificial layers, which are formed to serve as a structure corresponding to respective interconnect layers, with a conductive material (hereinafter, referred to as “the replacement”). In the replacement, after a sacrificial layer is removed and a space is formed, the space is embedded by a conductive material. The dummy pillar HR functions as a pillar supporting the inter-layer insulating film having a space when the replacement is performed. Each dummy pillar HR is not electrically coupled to the word lines WL and the select gate lines SGD and SGS.

The dummy pillar HR extends in the Z direction. The dummy pillar HR penetrates (passes through) the select gate line SGS, the word lines WL0 through WL7, and the select gate line SGD that are stacked in the Z direction. The arrangement of the dummy pillars HR is discretionarily determined.

### 1.1.5 Cross-Sectional Structure of Semiconductor Memory Device

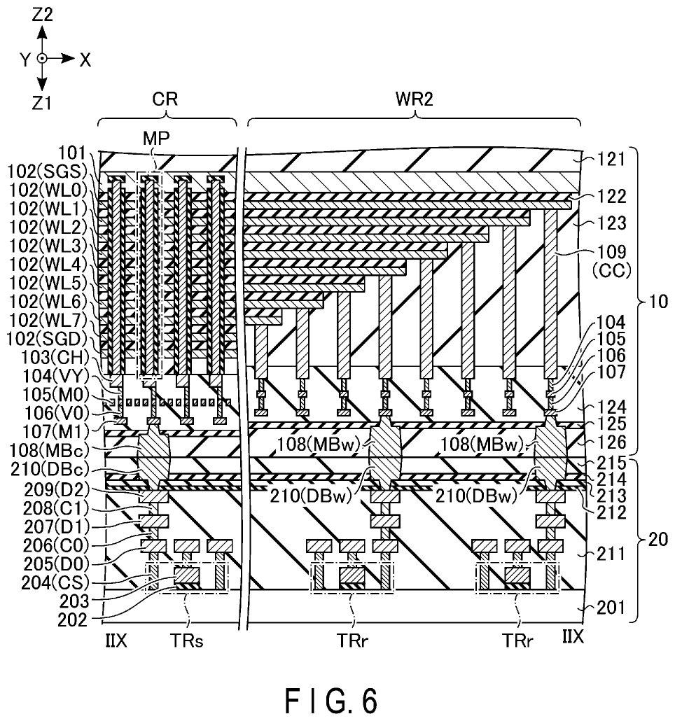

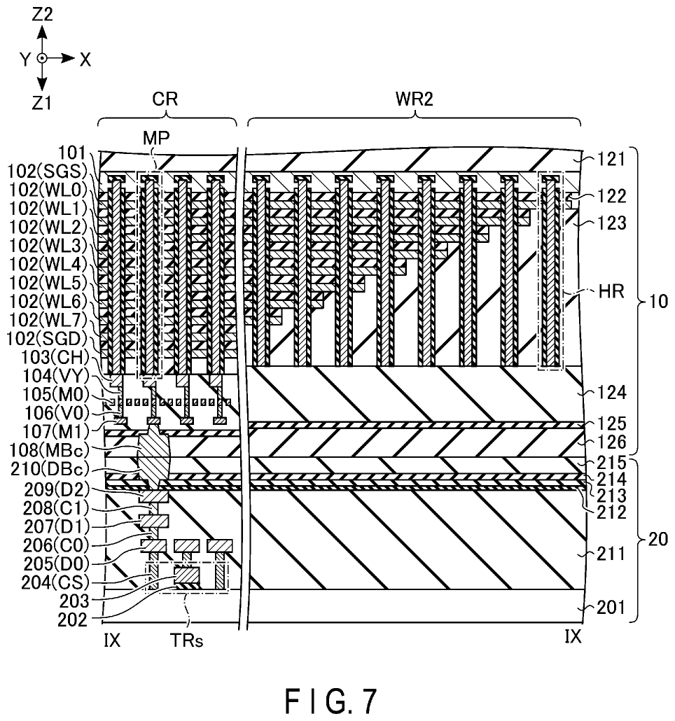

Next, an example of the bonded structure of the semiconductor memory device 1 is described with reference to FIGS. 6 and 7. FIG. 6 is a cross-sectional view of the semiconductor memory device 1, along line IIX-IIX of FIG. 5. FIG. 7 is a cross-sectional view of the semiconductor memory device 1, along line IX-IX of FIG. 5. Hereinafter, a cross section of the area of the array chip 10 in which the memory cell array 11 is provided (hereinafter, may be referred to as a “memory cell array region”) will be focused on to describe the embodiment. In the example of FIG. 7, only one dummy pillar HR is shown in each terrace to simplify the description. In the description hereinafter, the expression “approximately the same” is intended to cover errors due to manufacturing fluctuations. Hereinafter, the WL region WR2 will be mainly focused on; however, the description is applicable to the structure of the WL region WR1.

As shown in FIG. 6, the semiconductor memory device 1 has a bonded structure in which an array chip 10 and a circuit chip 20 are bonded.

The array chip 10 includes a semiconductor layer 101, interconnect layers 102, conductors 103 and 104, an M0 interconnect layers 105, conductors 106, M1 interconnect layers 107, electrodes 108, conductors 109, insulating layers 121 through 126, and memory pillars MP. The conductor 103 functions as the contact plug CH. The conductor 104 functions as a contact plug VY. The conductor 106 functions as a contact plug V0. The electrode 108 functions as a bonding pad MB. The conductor 109 functions as a contact plug CC. The number of the interconnect layers 102 arranged in the array chip 10 and the number of layers in a multiple-layered interconnect structure on the interconnect layers 102 can be discretionary designed.

The circuit chip 20 includes a semiconductor substrate 201, transistors TRs and TRr, gate insulating films 202, gate electrodes 203, conductors 204, DO interconnect layers 205, conductors 206, D1 interconnect layers 207, conductors 208, D2 interconnect layers 209, electrodes 210, and insulating layers 211 through 215. The conductor 204 functions as a contact plug CS. The conductor 206 functions as a contact plug C0. The conductor 208 functions as a contact plug C1. The electrode 210 functions as a bonding pad DB. The number of layers in a multiple-layered interconnect structure arranged in the circuit chip 20 can be discretionary designed.

### 1.1.5.1 Cross-Sectional Structure of Array Chip

A cross-sectional structure of the array chip 10 is hereinafter described with reference to FIGS. 6 and 7.

As shown in FIG. 6, the semiconductor layer 101 is provided on the surface facing in the Z1 direction of the insulating layer 121. The semiconductor layer 101 extends in the X direction and the Y direction. The semiconductor layer 101 of the memory cell array region functions as a source line SL. For example, the insulating layer 121 includes silicon oxide (SiO) as an insulating material. The semiconductor layer 101 includes silicon, for example.

In the cell area CR, a plurality of insulating layers 122 and a plurality of interconnect layers 102 are alternately stacked one by one on the surface facing in the Z1 direction of the semiconductor layer 101. In the example of FIG. 6, ten layers of the insulating layers 122 and ten layers of the interconnect layers 102 are alternately stacked one by one. In other words, a plurality of interconnect layers 102 which are stacked apart from each other in the Z1 direction are provided between the semiconductor layer 101 and the circuit chip 20. The interconnect layers 102 and the insulating layers 122 extend in the X direction. The insulating layer 122 includes, for example, silicon oxide. The interconnect layer 102 includes tungsten (W) as a conductive material, for example. In the example of FIG. 6, ten layers of the interconnect layers 102 function as the select gate line SGS, the word lines WL0 through WL7, and the select gate line SGD, in the order of nearness to the semiconductor layer 101, respectively.

In the WL region WR, the plurality of interconnect layers 102 and the plurality of insulating layers 122 are drawn out in a stepwise manner. The lengths of the plurality of interconnect layers 102 in the X direction respectively become shorter from the semiconductor layer 101 side toward the circuit chip 20 side.

A plurality of memory pillars MP are provided in the cell region CR. Each memory pillar MP corresponds to a single NAND string NS. The memory pillars MP have, for example, a columnar shape extending in the Z direction. The memory pillar MP penetrates (passes through) the plurality of insulating layers 122 and the plurality of interconnect layers 102. An end (bottom surfaces) in the Z2 direction of the memory pillar MP reach inside of the semiconductor layer 101. The structure of the memory pillars MP will be described later in detail.

An insulating layer 123 is provided in such a manner that it covers the insulating layers 122, the interconnect layers 102, and the memory pillars MP. The insulating layer 123 contains, for example, silicon oxide. In the present embodiment, in the Z direction, the positions of the surfaces facing in the Z1 direction (hereinafter, may be referred to as “the height positions”) of the insulating layer 123 differ between the cell region CR and the WL region WR. The distance from the bonded surface between the array chip 10 and the circuit chip 20 to the surface facing in the Z1 direction of the insulating layer 123 is longer in the WL region WR than in the cell region CR. In other words, the height from the surface facing in the Z1 direction of the semiconductor layer 101 to the surface facing in the Z1 direction of the insulating layer 123 is lower in the WL region WR than in the cell region CR.

A plurality of conductors 109 are provided in the WL region WR. The conductor 109 functions as a contact plug CC. The conductor 109 has a cylindrical shape extending in the Z direction, for example. The conductor 109 contains, for example, tungsten as a conductive material. The conductor 109 is coupled to any one of the interconnect layers 102 and is not electrically coupled to the other interconnect layers 102. The length of each of the conductors 109 in the Z direction depends on which interconnect layer 102 that the conductor 109 is coupled to. Of the conductors 109, one coupled to the interconnect layer 102 functioning as a select gate line SGS has a largest length in the Z direction (the height of the plug), and one coupled to the interconnect layer 102 functioning as the select gate line SGD has a smallest length.

A conductor 103 is provided on the surface facing in the Z1 direction of the memory pillar MP. The conductor 103 functions as a contact plug CH. The conductor 103 has a cylindrical shape extending in the Z direction, for example. The conductor 103 contains, for example, tungsten as a conductive material.

A plurality of conductors 104 are provided on the respective surfaces facing in the Z1 direction of the conductor 103 in the cell region CR and the conductor 109 in the WL region WR. The conductor 104 functions as a contact plug VY. The conductor 104 has a cylindrical shape extending in the z direction, for example. The conductor 104 contains, for example, tungsten as a conductive material.

An M0 interconnect layer 105 is provided on the surface facing in the Z1 direction of the conductor 104. For example, the plurality of M0 interconnect layers 105 in the cell region CR extend in the Y direction and are arranged along the X direction. Each of the plurality of memory pillars MP is electrically coupled to any one of the plurality of M0 interconnect layers 105 via the conductor 103 (contact plug CH) and the conductor 104 (contact plugs VY). The M0 interconnect layer 105 to which the memory pillar MP is coupled functions as a bit line BL. The M0 interconnect layer 105 contains copper (Cu) as a conductive material, for example.

A conductor 106 is provided on the surface facing in the Z1 direction of the M0 interconnect layer 105. The conductor 106 functions as a contact plug V0. The conductor 106 has a cylindrical shape extending in the Z direction, for example. The conductor 106 contains, for example, tungsten as a conductive material.

An M1 interconnect layer 107 is provided on the surface facing in the Z1 direction of the conductor 106. The M1 interconnect layer 107 contains tungsten as a conductive material, for example. The conductor 106 and the M1 interconnect layer 107 may be formed by a dual damascene method. In the dual damascene method, the patterns of the conductor 106 (contact plug V0) and the M1 interconnect layer 107 are processed in a batch. Subsequently, the conductor 106 and the M1 interconnect layer 107 are embedded with a conductive material (e.g., tungsten) in a batch.

The height positions of the conductors 104, the M0 interconnect layers 105, the conductors 106, and the M1 interconnect layers 107 in the cell region CR differ from those in the WL region WR. The distances from the bonded surface to the conductors 104, the M0 interconnect layers 105, the conductors 106, and the M1 interconnect layers 107 in the WL region WR are longer than in the cell region CR.

An insulating layer 124 is provided on the surface facing in the Z1 direction of the insulating layer 123. The insulating layer 124 covers the conductors 103 and 104, the M0 interconnect layers 105, the conductors 106, and the M1 interconnect layers 107. The insulating layer 124 contains, for example, silicon oxide. The film thickness of the insulating layer 124 in the cell region CR and that in the WL region WR are approximately the same. For this reason, similarly to the insulating layer 123, the height position of the surface facing in the Z1 direction of the insulating layer 124 differs between the cell region CR and the WL region WR. The distance from the bonded surface to the surface facing in the Z1 direction of the insulating layer 124 is longer in the WL region WR than in the cell region CR.

An insulating layer 125 made of a material differing from that of the insulating layer 124 is provided on the surface facing in the Z1 direction of the insulating layer 124. The insulating layer 125 functions as an etching stopper when the electrode 108 is formed by a dual damascene method. The insulating layer 125 contains, for example, silicon nitride (SiN) or silicon carbonitride (SiCN). It suffices that the insulating layer 125 is made of an insulating material with which the etching select ratio for the insulating layers 124 and 126 can be sufficiently achieved in the etching process of the dual damascene method.

The film thickness of the insulating layer 125 in the cell region CR and the film thickness of the insulating layer 125 in the WL region WR are approximately the same. For this reason, similarly to the insulating layers 123 and 124, the height position of the insulating layer 125 differs between the cell region CR and the WL region WR. The distance from the bonded surface to the surface facing in the Z1 direction of the insulating layer 125 is longer in the WL region WR than in the cell region CR.

An insulating layer 126 made of a material differing from that of the insulating layer 125 is provided on the surface facing in the Z1 direction of the insulating layer 125. The insulating layer 126 includes, for example, silicon oxide. The surface facing in the Z1 direction of the insulating layer 126 is flattened in both the cell region CR and the WL region WR. For this reason, the film thickness of the insulating layer 126 is thicker in the WL region WR than in the cell region CR. The surface facing in the Z1 direction of the insulating layer 126 is in contact with the insulating layer 215 of the circuit chip 20. In other words, the surface where the insulating layer 126 and the insulating layer 215 are in contact with each other is a bonded surface.

The electrode 108 is provided on the surface facing in the Z1 direction of the M1 interconnect layers 107. The electrode 108 contains copper as a conductive material, for example. The electrode 108 includes a bonding pad MB and a contact plug that couples the bonding pad MB to the M1 interconnect layer 107. The structure of the electrode 108 will be described in detail later.

The bonding pad MB is in contact with the bonding pad DB provided in the circuit chip 20 in the bonded surface. Hereinafter, if the bonding pad MB provided in the cell region CR is specified, it will be referred to as “bonding pad MBc”. Hereinafter, if the bonding pad MB provided in the WL region WR is specified, it will be referred to as “bonding pad MBw”. Each of the M0 interconnect layers 105 (bit lines BL) in the cell region CR is electrically coupled to any one of the bonding pads MBc. In other words, the memory pillar MP (the channel of the memory cell transistor MC) is electrically coupled to the bonding pad MBc via the bit line BL. Each of the plurality of conductors 109 (contact plugs CC) in the WL region WR is electrically coupled to any one of the bonding pads MBw. In other words, the word lines WL and the select gate lines SGD and SGS are electrically coupled to the bonding pads MBw via the conductors 109.

The electrode 108 is formed by, for example, a dual damascene method. If the electrode 108 is formed by the dual damascene method, the insulating layer 125 functions as an etching stopper of the bonding pad MB. Controllability of the heights of the bonding pad MB and the contact plug is improved through a use of the insulating layer 125. The bonding pad MB is formed on the same layer as the insulating layer 126. For this reason, the thickness of the bonding pad MB is determined by a film thickness of the insulating layer 126. In the present embodiment, the film thickness of the insulating layer 126 is thicker in the WL region WR than in the cell region CR. For this reason, the thickness of the bonding pad MBw is larger than the thickness of the bonding pad MBc. The thickness of the bonding pad MBw to which the select gate line SGD is coupled may be the same as that of the bonding pad MBw to which the word line WL or the select gate line SGS are coupled, or a thickness of the bonding pad MBc, or an intermediate thickness between the thickness of the bonding pad MBw to which the word line WL or the select gate line SGS is coupled and the thickness of the bonding pad MBc.

Next, dummy pillars HR are described.

As shown in FIG. 7, a plurality of dummy pillars HR are provided in the WL region WR. The structure of the dummy pillars HR of the present embodiment is the same as that of the memory pillars MP. The height from the surface facing in the Z1 direction of the semiconductor layer 101 to the surface facing in the Z1 direction of the insulating layer 123 is lower in the WL region WR than in the cell region CR. For this reason, the length of the dummy pillar HR in the Z direction (the height of the pillar) is shorter than that of the memory pillar MP. The structure of the dummy pillar HR may differ from that of the memory pillar MP.

For example, the dummy pillar HR provided on the terrace corresponding to the select gate line SGS penetrates the interconnect layer 102 functioning as the select gate line SGS. The dummy pillar HR provided on the terrace corresponding to the word line WL0 penetrates the interconnect layers 102 functioning as the select gate line SGS and the word line WL0. The dummy pillar HR provided on the terrace corresponding to the word line WL1 penetrates the interconnect layers 102 functioning as the select gate line SGS and the word lines WL0 and WL1. The dummy pillar HR provided on the terrace corresponding to the word line WL2 penetrates the interconnect layers 102 functioning as the select gate line SGS and the word lines WL0 through WL2. A similar structure is applicable to the dummy pillars HR provided on the terrace corresponding to the word line WL3 through WL7 and the select gate line SGD.

A conductor 103 or a conductor 104 is not provided on the surfaces facing in the Z1 direction of the dummy pillars HR. The dummy pillars HR are not electrically coupled to the M0 interconnect layers 105, etc.

### 1.1.5.2 Cross-Sectional Structure of Circuit Chip

A cross-sectional structure of the circuit chip 20 is hereinafter described with reference to FIG. 6.

As shown in FIG. 6, a plurality of transistors TR are provided on the surface facing in the Z2 direction of the semiconductor substrate 201. The transistor TR includes a gate insulating film 202, a gate electrode 203, and a source and a drain (not shown) formed in the semiconductor substrate 201. The gate insulating film 202 is provided on the surface facing in the Z2 direction of the semiconductor substrate 201. The gate electrode 203 is provided on the surface facing in the Z2 direction of the gate insulating film 202. The transistor TR used in the row decoder 23 is referred to as a “transistor TRr”, hereinafter. The transistor TR used in the sense amplifier 24 is referred to as a “transistor TRs”, hereinafter.

The conductors 204 are provided on the surfaces facing in the Z2 direction of the gate electrode 203 and the semiconductor substrate 201. The conductor 204 functions as a contact plug CS. The conductor 204 contains, for example, tungsten. The conductor 204 has a cylindrical shape extending in the Z direction, for example.

A D0 interconnect layer 205 is provided on the surface facing in the Z2 direction of the conductor 204. The D0 interconnect layer 205 contains tungsten as a conductive material, for example.

The conductor 206 is provided on the surface facing in the Z2 direction of the D0 interconnect layer 205. The conductor 206 functions as a contact plug C0. The conductor 206 contains, for example, tungsten or copper as a conductive material. The conductor 206 has a cylindrical shape extending in the Z direction, for example.

A D1 interconnect layer 207 is provided on the surface facing in the Z2 direction of the conductor 206. The D1 interconnect layer 207 contains tungsten or copper as a conductive material, for example. The D1 interconnect layers 207 and the conductors 206 may be formed in a batch by the dual damascene method.

The conductor 208 is provided on the surface facing in the z2 direction of the D1 interconnect layer 207. The conductor 208 functions as a contact plug C1. The conductor 208 contains copper as a conductive material, for example. The conductor 208 has a cylindrical shape extending in the Z direction, for example.

A D2 interconnect layer 209 is provided on the surface facing in the Z2 direction of the conductor 208. The D2 interconnect layer 209 contains copper as a conductive material, for example. The D2 interconnect layers 209 and the conductors 208 may be formed in a batch by the dual damascene method.

An insulating layer 211 is provided on the surface facing in the Z2 direction of the semiconductor substrate 201. The insulating layer 211 covers the transistors TR, the conductors 204, the D0 interconnect layers 205, the conductors 206, the D1 interconnect layers 207, the conductors 208, and the D2 interconnect layers 209. The insulating layer 211 includes, for example, silicon oxide.

An insulating layer 212 is provided on the surfaces facing in the Z2 direction of the insulating layer 211 and the D2 interconnect layers 209. The insulating layer 212 functions as a cap insulating layer (anti-oxidant layer) of the D2 interconnect layer 209. The insulating layer 212 contains, for example, silicon nitride or silicon carbonitride.

An insulating layer 213 is provided on the surface facing in the Z2 direction of the insulating layer 212. The insulating layer 213 includes, for example, silicon oxide.

An insulating layer 214 made of a material differing from that of the insulating layer 213 is provided on the surface facing in the Z2 direction of the insulating layer 213. The insulating layer 214 functions as an etching stopper when the electrode 210 is formed by the dual damascene method. The insulating layer 214 contains, for example, silicon nitride or silicon carbonitride. It suffices that the insulating layer 214 is made of an insulating material with which the etching select ratio for the insulating layers 213 and 215 can be sufficiently achieved in the etching process of the dual damascene method.

An insulating layer 215 made of a material differing from that of the insulating layer 214 is provided on the surface facing in the Z2 direction of the insulating layer 214. The insulating layer 215 includes, for example, silicon oxide. The surface facing in the Z2 direction of the insulating layer 215 is in contact with the insulating layer 126 of the array chip 10.

The electrode 210 is provided on the surface facing in the 22 direction of the D2 interconnect layer 209. The electrode 210 contains copper as a conductive material, for example. The electrode 210 includes a bonding pad DB and a contact plug that couples the bonding pad DB to the D2 interconnect layer 209. The structure of the electrode 210 will be described in detail later.

The bonding pad DB is in contact with the bonding pad MB provided in the array chip 10 in the bonded surface. Hereinafter, if the bonding pad DB coupled to the bonding pad MBc is specified, it will be referred to as “bonding pad DBc”. Hereinafter, if the bonding pad DB coupled to the bonding pad MBw is specified, it will be referred to as “bonding pad DBw”. The bonding pads DBc in the cell region CR are electrically coupled to the transistor TRs used in the sense amplifier 24. The bonding pads DBw in the WL region WR are electrically coupled to the transistor TRr used in the row decoder 23.

The electrode 210 is formed by, for example, the dual damascene method. If the electrode 210 is formed by the dual damascene method, the insulating layer 214 functions as an etching stopper of the bonding pad DB. Controllability of the heights of the bonding pad DB and the contact plug is improved through use of the insulating layer 214. The bonding pad DB is formed on the same layer as the insulating layer 215.

The number of layers in the multiple-layered interconnect structure provided between the transistors TR and the electrode 210 is discretionarily determined.

### 1.1.6 Cross-Sectional Structure of Bonding Pad

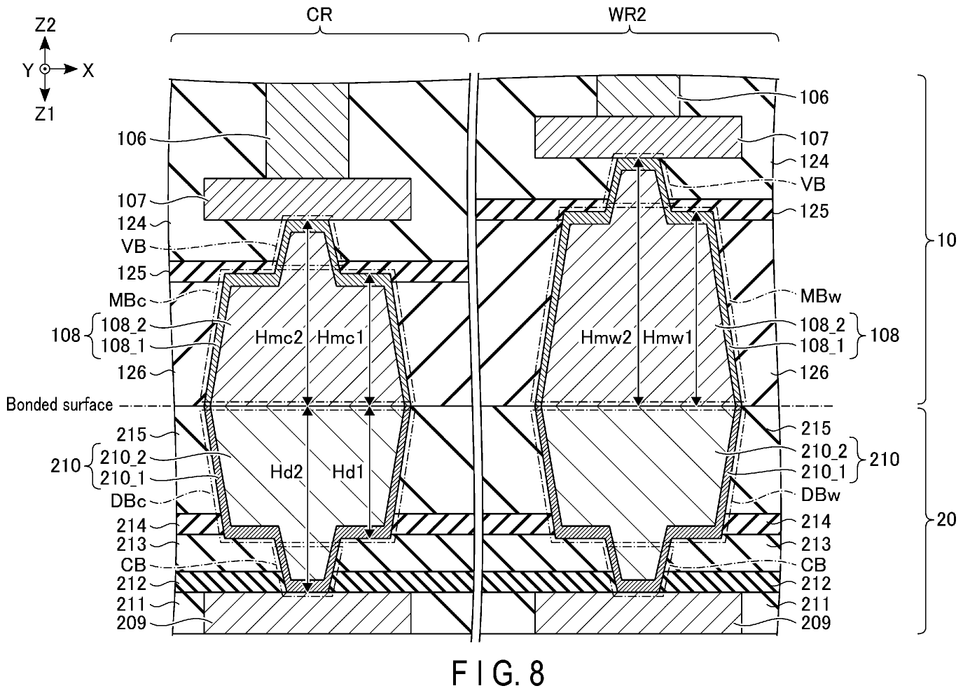

Next, a cross-sectional structure of the bonding pad BP is hereinafter described with reference to FIG. 8. FIG. 8 is a cross-sectional view of an example of the bonding pad BP. In the example of FIG. 8, the bonding pad BP consisting of the bonding pads MBC and DBc provided in the cell region CR and the bonding pad BP consisting of the bonding pads MBw and DBw provided in the WL region WR are shown.

First, the electrode 108 of the array chip 10 is described.

As shown in FIG. 8, the electrode 108 includes a bonding pad MB and a contact plug VB that couples the bonding pad MB to the M1 interconnect layer 107.

The bonding pad MB has a truncated cone shape in which the area size of the surface facing in the Z1 direction of the bonding pad MB (hereinafter, “the lower surface of the bonding pad MB”) is larger than the area size of the surface facing in the Z2 direction (hereinafter, “the upper surface of the bonding pad MB”). The shapes of the upper surface and lower surface of the bonding pad MB are not limited. The bonding pad MB may be in a truncated pyramid shape or a truncated cone shape. The side surfaces of the bonding pad MB may have a tapered shape. The lower surface of the bonding pad MB is a bonded surface.

The contact plug VB couples the bonding pad MB to the M1 interconnect layer 107. The contact plug VB has a truncated cone shape projecting from the upper surface of the bonding pad MB toward the 22 direction. In other words, the contact plug VB is in contact with the upper surface of the bonding pad MB. The area size of the surface facing in the Z1 direction of the contact plug VB (hereinafter, “the lower surface of the contact plug VB”) is larger than the area size of the surface facing in the Z2 direction (hereinafter, “the upper surface of the contact plug VB”). The area size of the lower surface of the contact plug VB is smaller than that of the upper surface of the bonding pad MB. The shapes of the upper surface and lower surface of the contact plug VB are not limited. The contact plug VB may be in a truncated pyramid shape or a truncated cone shape. The side surfaces of the contact plug VB may have a tapered shape. The upper surface of the contact plug VB is in contact with the M1 interconnect layer 107.

For example, the bonding pads MB and the contact plugs VB are formed in a batch by the dual damascene method. The bonding pad MB is provided on the same layer as the insulating layer 126. The upper surface of the bonding pad MB reaches the insulating layer 125. The insulating layer 125 functions as an etching stopper of the bonding pad MB and a mask of the contact plug VB. The contact plug VB is provided within the insulating layer 124. In the example of FIG. 8, the surface facing in the Z1 direction of the M1 interconnect layer 107 is in contact with the insulating layer 124 but a cap insulating layer (anti-oxidant layer) may be provided on the surface facing in the Z1 direction of the M1 interconnect layer 107. For example, if the M1 interconnect layer 107 contains copper as a conductive layer, silicon nitride or silicon carbonitride may be provided as a cap insulating layer. In this case, the upper surface of the bonding pad MB may pass through the insulating layer 125 and reach the insulating layer 124.

The electrode 108 includes a barrier metal (conductor) 108_1 and a conductor 108_2. The barrier metal 108_1 functions as an antioxidant layer, a diffusion preventing layer, and an adhesion layer of the conductor 108_2. The barrier metal 108_1 is formed in such a manner that it covers the side surface and the upper surface of the bonding pad MB and those of the contact plug VB. The barrier metal 108_1 is in contact with the M1 interconnect layer 107 and insulating layers 124 through 126. The conductor 108_2 is in contact with and provided within the barrier metal 108_1, and embeds the bonding pad MB and the contact plug VB. The barrier metal 108_1 contains, for example, titanium (Ti), titanium nitride (TiN), tantalum (Ta), or tantalum nitride (TaN). The barrier metal 108_1 may be a stacked film of these materials. The conductor 108_2 contains copper as a conductive material, for example.

The thickness of the bonding pad MBw provided in the WL region WR is larger than the thickness of the bonding pad MBc provided in the cell region CR. The area size of the lower surface of the bonding pad MBw is approximately the same as the area size of the lower surface of the bonding pad MBc. For this reason, the volume of the bonding pad MBw is larger than that of the bonding pad MBc.

More specifically, suppose the length from the bonded surface to the upper surface of the bonding pad MBw in the WL region WR is Hmw1. Suppose the length from the bonded surface to the upper surface of the contact plug VB, in other words the length of the electrode 108 with respect to the Z direction, is Hmw2. Suppose the length from the bonded surface to the upper surface of the bonding pad MBc in the cell region CR is Hmc1. Suppose the length from the bonded surface to the upper surface of the contact plug VB, in other words the length of the electrode 108 with respect to the z direction, is Hmc2. The length Hmw1 and the length Hmc1 are in the relationship of Hmw1>Hmc1. The length (Hmw2−Hmw1) of the contact plug VB in the WL region WR with respect to the Z direction is approximately the same as the length (Hmc2−Hmc1) of the contact plug VB in the cell region CR with respect to the Z direction. Therefore, the length Hmw2 and the length Hmc2 are in the relationship of Hmw2>Hmc2.

The height position of the insulating layer 125 differs between the cell region CR and the WL region WR. In other words, the height position of the insulating layer 125 in contact with the bonding pad MBc differs from that of the insulating layer 125 in contact with the bonding pad MBw. For this reason, the film thickness of the insulating layer 126 differs between the cell region CR and the WL region WR. The film thickness of the insulating layer 126 of the cell region CR, in other words, the distance from the bonded surface to the insulating layer 125 in the cell region CR, is approximately the same as the length Hmc1 of the bonding pad MBc, for example. The film thickness of the insulating layer 126 of the WL region WR, in other words, the distance from the bonded surface to the insulating layer 125 in the WL region WR, is approximately the same as the length Hmw1 of the bonding pad MBw, for example.

If the electrode 108 (bonding pad MB) and the electrode 210 (bonding pad DB) are bonded in the process of bonding the array chip 10 and the circuit chip 20, annealing is performed. The length Hmw1 of the bonding pad MBw is larger than the length Hmc1 of the bonding pad MBc. In other words, the volume of the bonding pad MBw is larger than that of that of the bonding pad MBC. In this case, the thermal expansion amount of the conductor 108_2 as a result of annealing is greater in the bonding pad MBw than in the bonding pad MBC. For this reason, the contact area between the conductor 108_2 and the conductor 210_2 increases in the WL region WR. As a result, defects in bonding in the bonding pad MBw and the bonding pad DBw can be reduced. It is preferable that a difference between the thickness of the bonding pad MBw and the thickness of the bonding pad MBC, (Hmw1−Hmc1), be 50 nm±40 nm. If the thickness difference (Hmw1−Hmc1) becomes greater than 90 nm, for example, residues of a conductive material are easily produced in a step difference when the conductive material that embeds the M1 interconnect layer 107 is removed by CMP. If the thickness difference (Hmw1−Hmc1) becomes smaller than 10 nm, it becomes difficult to obtain the above-described effect in improving defects in the bonding in the WL region WR.

In the cell region CR, the ratio of the length (Hmc2−Hmc1) of the contact plug VB to the length Hmc2 of the electrode 108 is preferably equal to or smaller than 40%. Furthermore, in the WL region WR, it is preferable that the ratio of the length (Hmw2−Hmw1) of the contact plug VB to the length Hmw2 of the electrode 108 be equal to or smaller than 35%. If the ratio of the contact plug VB becomes larger than those values, the tensile stress that pulls the conductor 108_2 of the contact plug VB toward the bonding pad MB increases when annealing is performed. As a result, a break between the electrode 108 and the M1 interconnect layer 107 easily occurs in the bottom of the contact plug VB. The aspect ratio of the contact plug VB (the ratio of the height of the contact plug VB to the diameter of the lower surface of the contact plug VB) is preferably equal to or smaller than 1.5. If the aspect ratio of the contact plug VB becomes larger than 1.5, in other words, if the ratio of the height of the contact plug VB becomes greater, the tensile stress increases and a break in the electrode 108 and the M1 interconnect layer easily occurs.

Next, the electrode 210 of the circuit chip 20 is described.

The electrode 210 includes a bonding pad DB and a contact plug CB that couples the bonding pad DB to the D2 interconnect layer 209. In the present embodiment, the case where the shape of the electrode 210 in the cell region CR and the shape of the electrode 210 in the WL region WR are approximately the same is described. Similarly to the electrode 108 of the array chip 10, the thickness of the electrode 210 in the WL region WR may be greater than that of the electrode 210 in the cell region CR.

The bonding pad DB has a truncated cone shape in which the area size of the surface facing in the z2 direction of the bonding pad DB (hereinafter, “the upper surface of the bonding pad DB”) is larger than the area size of the surface facing in the Z1 direction (hereinafter, “the lower surface of the bonding pad DB”). The shapes of the upper surface and lower surface of the bonding pad DB are not limited. The shape of the upper surface of the bonding pad DB is approximately the same as the shape of the lower surface of the bonding pad MB of the electrode 108. The side surfaces of the bonding pad DB may have a tapered shape. The upper surface of the bonding pad DB is a bonded surface.

The contact plug CB couples the bonding pad DB to the D2 interconnect layer 209. The contact plug CB has a truncated cone shape projecting from the lower surface of the bonding pad DB toward the Z1 direction. In other words, the contact plug CB is in contact with the lower surface of the bonding pad DB. The area size of the surface facing in the 22 direction of the contact plug CB (hereinafter, “the upper surface of the contact plug CB”) is larger than the area size of the surface facing in the Z1 direction (hereinafter, “the lower surface of the contact plug CB”). The area size of the upper surface of the contact plug CB is smaller than that of the lower surface of the bonding pad DB. The shapes of the upper surface and lower surface of the contact plug CB are not limited. The contact plug CB may be in a truncated pyramid shape or a truncated cone shape. The side surfaces of the contact plug CB may have a tapered shape. The lower surface of the contact plug CB is in contact with the D2 interconnect layer 209.

For example, the bonding pads DB and the contact plugs CB are formed in a batch by the dual damascene method. The bonding pad DB is provided on the same layer as the insulating layer 215. The lower surface of the bonding pad DB may pass through the insulating layer 214 and reach the insulating layer 213. The insulating layer 214 functions as an etching stopper of the bonding pad DB and a mask of a contact plug CB. The contact plug CB passes through the insulating layer 213 and the insulating layer 212. In the example of FIG. 8, the insulating layer 212 is provided as a cap insulating layer on the surface facing in the Z2 direction of the D2 interconnect layer 209, the insulating layer 212 may be omitted, on the other hand. For example, if the D2 interconnect layer 209 contains tungsten as a conductive material, the insulating layer 212 can be omitted. In this case, the lower surface of the bonding pad DB reaches inside the insulating layer 214 in a manner similar to the upper surface of the bonding pad MB.

The electrode 210 includes a barrier metal (conductor) 210_1 and a conductor 210_2. The barrier metal 210_1 functions as an antioxidant layer, a diffusion preventing layer, and an adhesion layer of the conductor 210_2. The barrier metal 210_1 is formed in such a manner that it covers the side surface and the lower surface of the bonding pad DB and those of the contact plug CB. The barrier metal 210_1 is in contact with the D2 interconnect layer 209 and insulating layers 212 through 215. The conductor 210_2 is in contact with and provided within the barrier metal 210_1, and embeds the bonding pad DB and the contact plug CB. The barrier metal 210_1 contains, for example, titanium, titanium nitride, tantalum, or tantalum nitride. The barrier metal 210_1 may be a stacked film of these materials. The conductor 210_2 contains copper as a conductive material, for example.

The thickness of the bonding pad DB is approximately the same in the cell region CR and the WL region WR. In other words, the thickness of the bonding pad DBc is approximately the same as that of the bonding pad DBw. In other words, the thickness of the electrode 210 of the cell region CR is approximately the same as that of the electrode 210 in the WL region WR.

Suppose the length from the bonded surface to the lower surface of the bonding pad DB is Hd1. Suppose the length from the bonded surface to the lower surface of the contact plug CB, in other words the length of the electrode 210 with respect to the Z direction, is Hd2. For example, if the length Hd2 and the length Hmc2 are approximately the same in the cell region CR and the WL region WR, in other words, if the shape of the electrode 108 in the cell region CR and the shape of the electrode 210 are approximately the same, the ratio of the length (Hd2−Hd1) of the contact plug CB with respect to the z direction to the length Hd2 in the electrode 210 is preferably equal to or smaller than 40%. Similarly to the electrode 108, the aspect ratio of the contact plug CB (the ratio of the height of the contact plug CB to the diameter of the upper surface of the contact plug CB) is preferably equal to or smaller than 1.5.

For example, if copper is used in the conductors 108_2 and 210_2, the copper of the conductor 108_2 and the copper of the conductor 210_2 become integrated, and it would be difficult to confirm the boundary therebetween. The bonding can however be confirmed from any warpage due to a deviation in bonding between the electrodes 108 and 210, and any deviation in positions of the barrier metal 108_1 and the barrier metal 210_1 (a discontinuous portion in the side surface).

If the electrodes 108 and 210 are formed by the dual damascene method, the side surfaces thereof have a tapered shape. For this reason, in the cross-sectional structure of the bonding pad BP along the Z-direction, the side wall of the part where the electrode 108 and the electrode 210 are bonded to each other does not have a linear shape but the part forms a non-rectangular shape.

If the electrode 108 and the electrode 210 are bonded to each other, the lower surface, side surface, and upper surface constituting these elements are covered by a barrier metal. On the other hand in a typical interconnect layer using copper, a cap insulating layer (SiN or SiCN, etc.) having a function of preventing oxidization of copper is provided on the upper surface of copper but not with a barrier metal. For this reason, it is possible to distinguish the electrodes 108 and 210 from a typical interconnect layer, even if no deviation occurs in the bonding.

### 1.1.7 Cross-Sectional Structure of Memory Cell Array

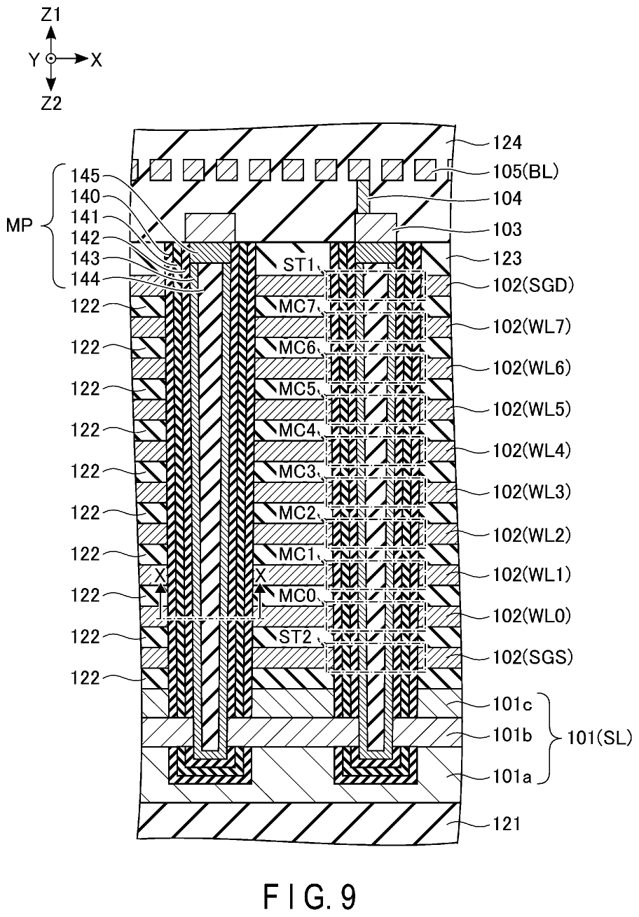

Next, a cross-sectional structure of the memory cell array 11 is described, with reference to FIG. 9. FIG. 9 is a cross-sectional view showing an example of the memory cell array 11. FIG. 9 shows two memory pillars MP included in the memory cell array 11.

As shown in FIG. 9, the semiconductor layer 101 includes, for example, three semiconductor layers 101a, 101b, and 101c. A semiconductor layer 101b is provided on the surface facing in the Z1 direction of the semiconductor layer 101a. A semiconductor layer 101c is provided on the surface facing in the Z1 direction of the semiconductor layer 101b. The semiconductor layer 101b is formed by, for example, replacing the sacrificial layer provided between the semiconductor layer 101a and the semiconductor layer 101c. The semiconductor layers 101a through 101c contain silicon, for example. The semiconductor layers 101a to 101c contain phosphorous (P) as impurities of the semiconductor, for example.

Ten layers of the insulating layers 122 and ten layers of the interconnect layers 102 are alternately stacked one by one on the surface facing in the Z1 direction of the semiconductor layer 101. In the example of FIG. 9, ten layers of the interconnect layers 102 function as the select gate line SGS, the word lines WL0 through WL7, and the select gate line SGD, in order of nearness to the semiconductor layer 101, respectively. A plurality of the interconnect layers 102 respectively functioning as the select gate line SGS or the select gate line SGD may be provided. As the conductive material of the interconnect layer 102, a stacked structure of titanium nitride and tungsten may be used, for example. In this case, titanium nitride is formed so as to cover tungsten. Titanium nitride has a function as a barrier layer to suppress oxidization of tungsten and as a layer for improving adhesion of tungsten, when tungsten is deposited by a chemical vapor deposition (CVD) method. The interconnect layer 102 may contain a high dielectric constant material, such as aluminum oxide (AlO), etc. In this case, the high dielectric constant material is formed so as to cover the conductive material. For example, in each interconnect layer 102, a high dielectric constant material is provided so as to be in contact with the insulating layer 122 provided above and below the interconnect layer 102 and the side surface of the memory pillars MP. Furthermore, titanium nitride is provided so as to be in contact with the high dielectric constant material. Furthermore, tungsten is provided so as to be in contact with titanium nitride and to embed the inside of the interconnect layer 102. For example, if aluminum oxide is provided as a high dielectric constant material, the memory cell transistors MC may be referred to as a MANOS (metal-aluminum-nitride-oxide-silicon) type.

An insulating layer 123 is provided on the surface facing in the Z1 direction of the interconnect layer 102 functioning as the select gate line SGD.

A plurality of memory pillars MP are provided in the memory cell array 11. For example, the memory pillars MP have approximately a cylindrical shape extending in the Z direction. The memory pillars MP penetrate ten layers of the interconnect layers 102. The bottom surface of the memory pillars MP reach the semiconductor layer 101. The memory pillars MP may be a structure in which multiple pillars are coupled in the z direction.

Next, an internal configuration of the memory pillar MP is described. The memory pillar MP includes the block insulating film 140, the charge storage film 141, the tunnel insulating film 142, the semiconductor film 143, and the core film 144, and the cap film 145.

On a part of the side surface and the bottom surface facing in the 22 direction of the memory pillar MP, the block insulating film 140, the charge storage film 141, and the tunnel insulating film 142 are stacked in this order, from the outer surface. More specifically, the block insulating film 140, the charge storage film 141, and the tunnel insulating film 142 stacked on the side surface of the memory pillar MP are removed from the same layer as the semiconductor layer 101b and in the vicinity thereof. The semiconductor film 143 is provided so as to be in contact with the side surface and the bottom surface of the tunnel insulating film 142 and the semiconductor layer 101b. The semiconductor film 143 is an area where the channels of the memory cell transistors MC and the select transistors ST1 and ST2 are formed. The inside of the semiconductor film 143 is embedded by the core film 144. In the upper part of the memory pillar MP with respect to the Z1 direction, the cap film 145 is provided on the upper end of the semiconductor film 143 and the core film 144. The side surface of the cap film 145 is in contact with the tunnel insulating film 142. The cap film 145 contains silicon, for example. The conductor 103 is provided on the surface facing in the Z1 direction of the cap film 145. The conductor 104 is provided on the surface facing in the 21 direction of the conductor 103. The conductor 104 is coupled to the M0 interconnect layer 105 functioning as a bit line BL.

The memory cell transistors MC0 through MC7 are configured by respectively combining the memory pillar MP and the interconnect layers 102 functioning as the word lines WL0 through WL7. Similarly, the select transistor ST1 is configured by combining the memory pillar MP and the interconnect layer 102 functioning as the select gate line SGD. The select transistor ST2 is configured by combining the memory pillar MP and the interconnect layer 102 functioning as the select gate line SGS. With these components, the memory pillars MP are each capable of functioning as one NAND string NS.

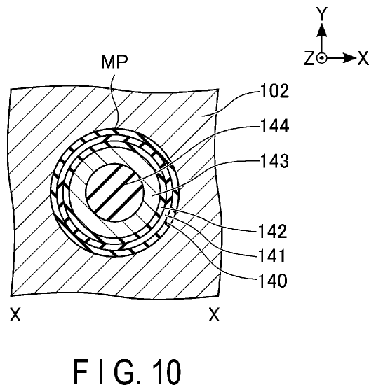

An example of the cross-sectional structure of the memory pillar MP along the XY plane is described with reference to FIG. 10. FIG. 10 is a sectional view taken along the line X-X indicated in FIG. 9. More specifically, FIG. 10 shows a cross-sectional structure of the memory pillar MP at the layer embracing the interconnect layer 102.

In the cross-section embracing the interconnect layer 102, the core film 144 is at, for example, the central part of the memory pillar MP. The semiconductor film 143 surrounds the side face of the core film 144. The tunnel insulating film 142 surrounds the side face of the semiconductor film 143. The charge storage film 141 surrounds the side face of the tunnel insulating film 142. The block insulating film 140 surrounds the side face of the charge storage film 141. The interconnect layer 102 surrounds the side face of the block insulating film 140.

The semiconductor film 143 serves as a channel (current path) for the memory cell transistors MC0 to MC7 and the select transistors ST1 and ST2. The tunnel insulating film 142 and the block insulating film 140 both contain for example, silicon oxide. The charge storage film 141 has a function of accumulating charges. The charge storage film 141 includes silicon nitride (SiN) for example.

### 1.2 Method of Manufacturing Memory Cell Array and Electrode

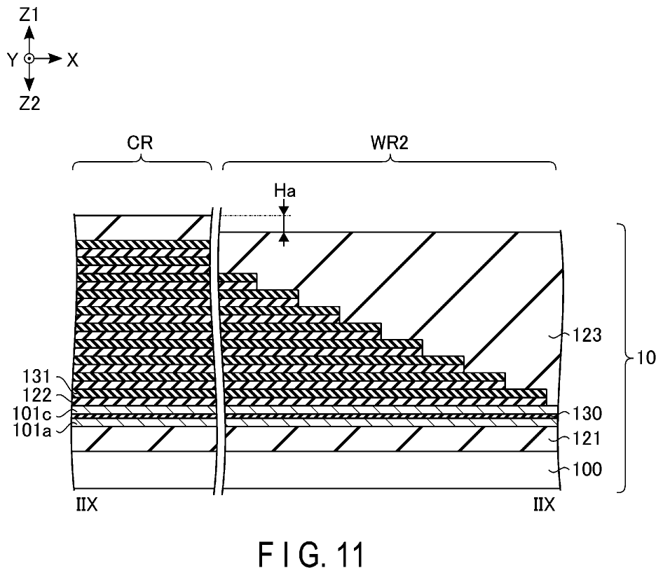

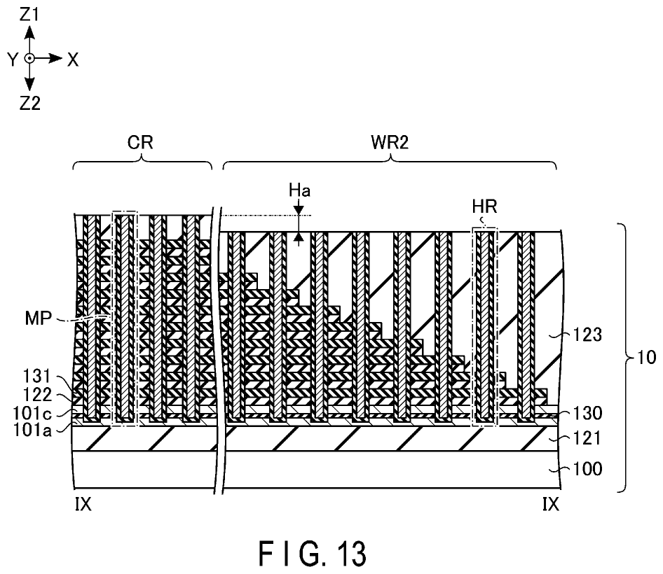

Next, an example of a method of manufacturing the memory cell array 11 and the electrodes 108 is described, with reference to FIGS. 11-20. FIGS. 11 to 20 are cross-sectional views indicating the process of manufacturing the memory cell array 11 and the electrodes 108 of the array chip 10. FIGS. 11, 12, and 14-20 show examples of cross-sectional structures of the array chip 10 viewed along line IIX-IIX of FIG. 5. FIG. 13 shows an example of a cross-sectional structure of the array chip 10 viewed along line IX-IX of FIG. 5.

As shown in FIG. 11, the insulating layer 121 is first formed on the semiconductor substrate 100 of the array chip 10. The semiconductor substrate 100 of the array chip 10 may be removed after the array chip 10 and the circuit chip 20 are bonded. In other words, the semiconductor substrate 100 may be omitted in the semiconductor memory device 1 having a bonded structure. Next, the semiconductor layer 101 is deposited on the insulating layer 121. More specifically, a semiconductor layer 101a, a sacrificial layer 130, and a semiconductor layer 101c are deposited on the insulating layer 121 in this order. The sacrificial layer 130 is later replaced with the semiconductor layer 101b. Next, the insulating layers 122 and the sacrificial layers 131 are alternately stacked one by one in the memory cell array 11. The sacrificial layers 131 are later replaced with the interconnect layers 102. The sacrificial layer 131 contains silicon nitride, for example. In the WL region WR, after the steps of ten layers of the sacrificial layers 131 are formed, the insulating layer 123 is deposited so as to cover the entire surface facing in the Z1 direction of the semiconductor substrate 100. Next, chemical mechanical polishing (CMP) is performed on the insulating layer 123. At this time, the insulating layer 123 is not completely flattened, and a step having a height Ha is formed between the cell region CR and the WL region WR. A method of forming a step having the height Ha in the insulating layer 123 is not limited to CMP performed on the insulating layer 123. For example, a step may be formed by photo-lithography and dry etching.

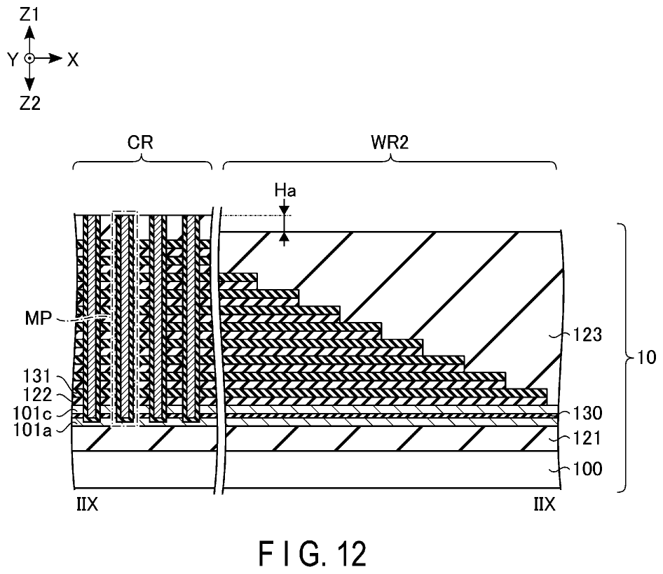

As shown in FIG. 12, the memory pillars MP are formed in the cell region CR. At this time, as shown in FIG. 13, a plurality of dummy pillars HR are provided in the WL region WR. Hereinafter, the description is made with a focus on the memory pillars MP. More specifically, memory holes corresponding to the memory pillars MP are formed. The memory holes penetrate the insulating layer 123, the sacrificial layers 131, the insulating layers 122, the semiconductor layer 101c, and the sacrificial layer 130. The bottom surfaces the memory holes reach inside the film of the semiconductor layer 101a. The block insulating film 140, the charge storage film 141, the tunnel insulating film 142, the semiconductor film 143, and the core film 144 are deposited in this order to embed the memory holes. Next, after the semiconductor film 143 and the core film 144 in the upper portion of the memory pillars MP are removed, a cap film 145 is deposited. Thereafter, the block insulating film 140, the charge storage film 141, the tunnel insulating film 142, the semiconductor film 143, the core film 144, and the cap film 145 on the surface facing in the Z1 direction of the insulating layer 123 are removed.

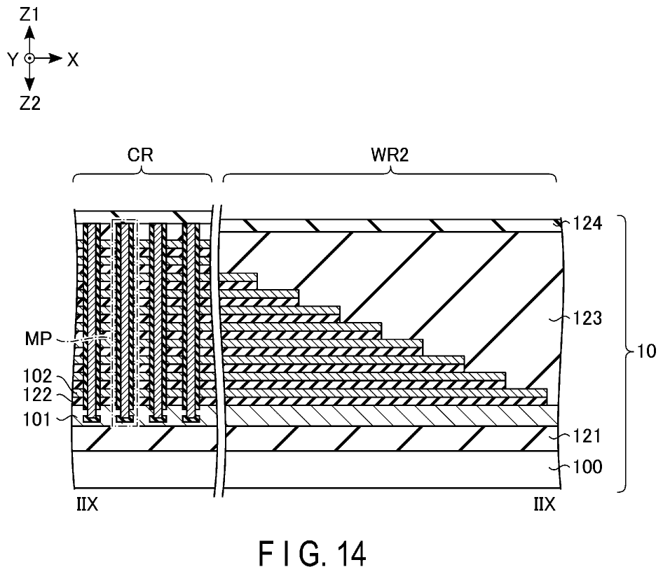

As shown in FIG. 14, the insulating layer 124, for example, corresponding to the height of the conductor 103 is deposited to protect the surface of the memory pillar MP. Next, the sacrificial layer 130 is replaced with the semiconductor layer 101b. More specifically, slits SLT are formed in the not-shown region of the memory cell array 11. The bottom surface of the slit SLT reaches inside the film of the sacrificial layer 130. For example, the sacrificial layer 130 is removed from the side surface of the slits SLT by wet etching. At the same time, parts of the block insulating film 140, the charge storage film 141, and the tunnel insulating film 142, which are located at the same layer as the sacrificial layer 130, are also removed. The semiconductor layer 101b is formed in the region from which the sacrificial layer 130, the block insulating film 140, the charge storage film 141, and the tunnel insulating film 142 are removed. As a result, the semiconductor film 143 in the memory pillar MP is coupled to the semiconductor layer 101.

Next, the sacrificial layers 131 are replaced with the interconnect layers 102. More specifically, for example, the sacrificial layers 131 are removed from the side surface of the slits SLT by wet etching. The interconnect layers 102 are formed in the region from which the sacrificial layers 131 are removed.

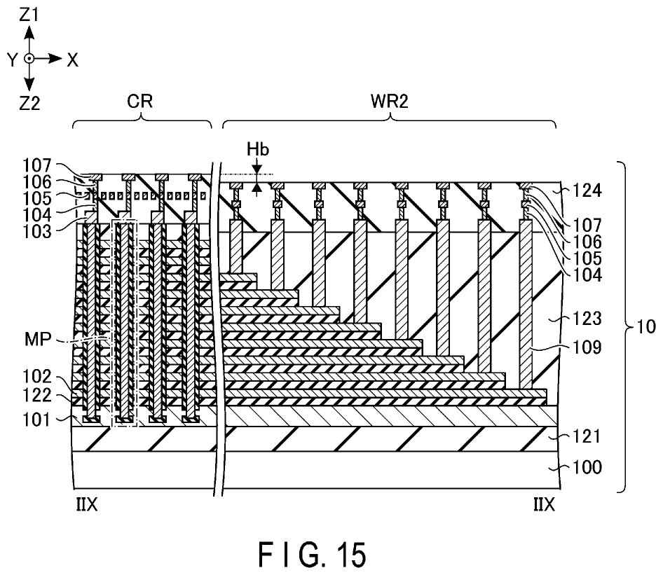

As shown in FIG. 15, the conductors 103 and 109 are formed. More specifically, hole patterns corresponding to the conductors 103 and the conductors 109 are formed, for example. After the hole patterns are embedded by a conductive material, the residual conductive material on the insulating layer 124 is removed by CMP.

By a similar procedure, the conductors 104, the M0 interconnect layers 105, the conductors 106, and the M1 interconnect layers 107 are successively formed. At this time, the step of the height Hb remains between the cell region CR and the WL region WR. The height Hb is equal to or smaller than a height Ha. By the CMP process in the above-described formation of the multiple layered interconnect structure, the step of the height Ha may be reduced to the height Hb.

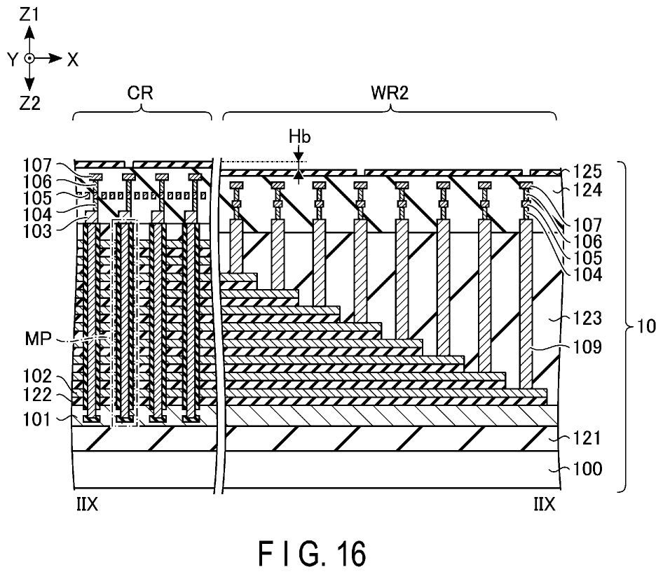

As shown in FIG. 16, the insulating layers 124 and 125 are deposited. Next, a mask pattern for forming the contact plugs VB is formed by processing the insulating layer 125.

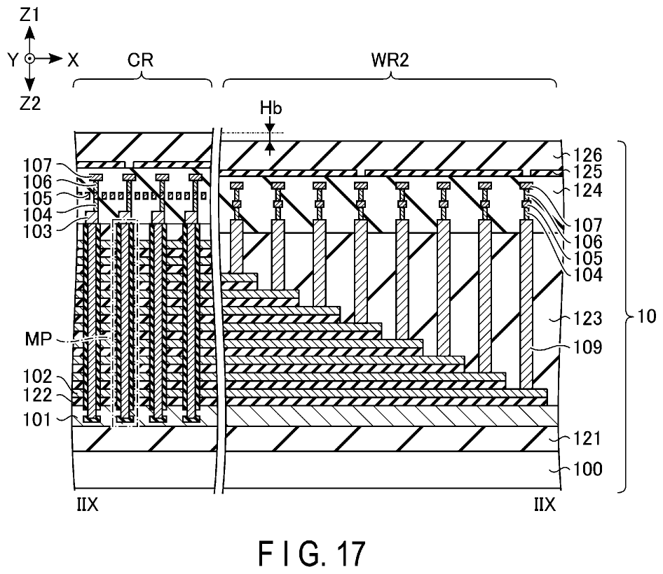

As shown in FIG. 17, the insulating layer 126 is formed. At this time, the step of the height Hb remains between the cell region CR and the WL region WR.

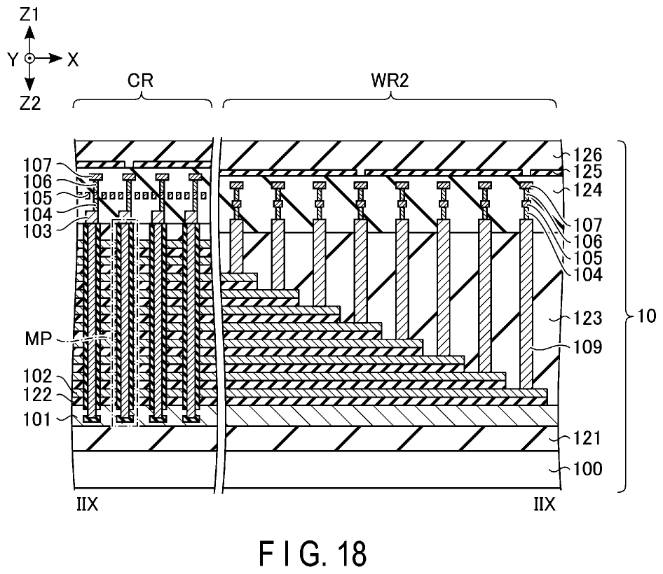

As shown in FIG. 18, the surface of the insulating layer 126 is flattened by CMP. The step between the cell region CR and the WL region WR is thereby almost gone. As a result, the film thickness of the insulating layer 126 of the WL region WR becomes thicker than that of the insulating layer 126 in the cell region CR.

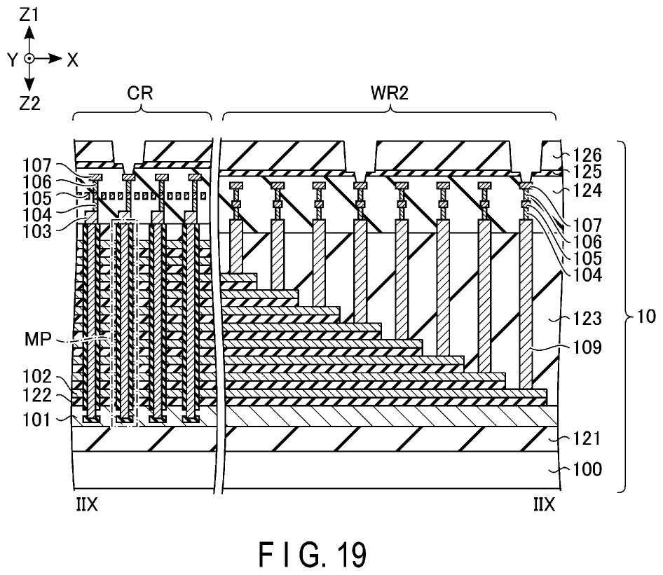

As shown in FIG. 19, the pattern of the electrode 108 is formed by the dual damascene method. More specifically, a resist mask corresponding to the bonding pads MB of the electrodes 108 is formed on the insulating layer 126, for example. Next, patterns corresponding to the bonding pads MB and the contact plugs VB of the electrodes 108 are formed in a batch by dry etching. At this time, the insulating layer 126 is first etched so as to form patterns of the bonding pads MB whose bottom surface reaches the insulating layer 125. If the insulating layer 125 is exposed, the insulating layer 125 functions as a mask of the contact plugs VB. Furthermore, the insulating layer 124 in the opening portions of the insulating layer 125 is etched. The patterns of the contact plugs VB are thereby formed. The film thickness of the insulating layer 126 of the WL region WR is thicker than that of the insulating layer 126 in the cell region CR. For this reason, the thickness of the bonding pad MBw in the WL region WR is larger than the thickness of the bonding pad MBc in the cell region CR.

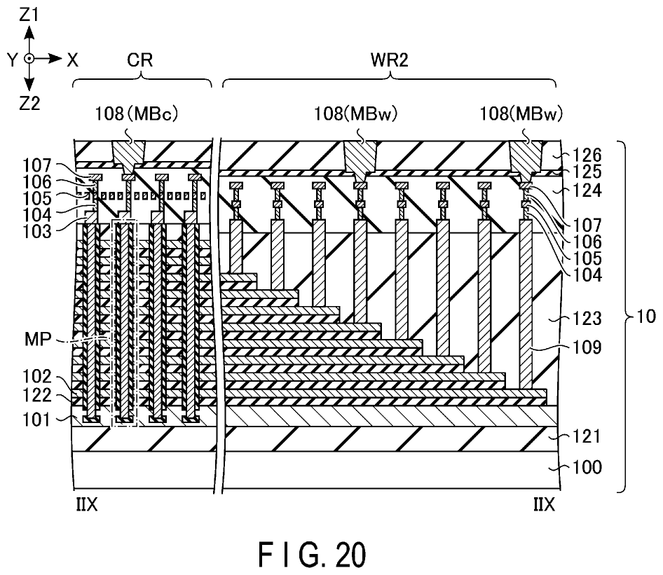

As shown in FIG. 20, the electrode 108 is formed. More specifically, the barrier metal 108_1 and the conductor 108_2 are successively deposited. Next, the electrodes 108 are formed by removing residual barrier metal 108_1 and the conductor 108_2 on the insulating layer 126 by CMP.

### 1.3 Advantageous Effects of Present Embodiment

A semiconductor memory device in which defects in bonding are reduced can be provided by a configuration according to the present embodiment. Such advantageous effects are explained in detail.

In the bonded structure in which an array chip and a circuit chip are bonded to each other, electrodes (bonding pads) on the array chip side and electrodes (bonding pads) on the circuit chip side are bonded each other. For example, each electrode is formed by CMP. In the case where the electrodes are formed by CMP, a conductive layer (e.g., copper) for embedding the electrodes may be in a concave shape with respect to the bonded surface, namely the surface of the insulating layer, because of the influence of dishing. For this reason, an effective contact area between the conductive material of the electrode on the array chip side and the conductive material of the electrode on the circuit chip side may be smaller than a facing area between the electrode patterns in the insulating layer on the array chip side and in the insulating layer on the circuit chip side. In this case, in the bonded surface, a gap may occur within the bonding pad. For example, if there is a gap, even if the device is determined to be non-defective in an initial examination after the bonding process, the possibility that electro migration of a conductive material will be caused by electrification thereafter and a break will occur is high. This tendency is more significant in the bonding pad in the WL region that corresponds to the word line to which a relatively high voltage is applied during a write operation, a read operation, and an erase operation than in the bonding pad in the cell region.

Furthermore, if annealing is performed during the bonding process, a tensile stress is produced in a conductive material that embeds the electrode. For example, the electrode has a bonding pad and a contact plug coupled to the bonding pad and the bonding pad and the contact plug are embedded by the same conductive material. In this case, the conductive material of the contact plug may be pulled to the bonding pad side by a tensile stress, and defects due to a break in the contact plug may occur.

In contrast, in the configuration according to the present embodiment, it is possible to increase the length Hmw1 of the bonding pad MBw of the array chip 10 with respect to the Z direction more than the length Hmc1 of the bonding pad MBc with respect to the Z direction. In other words, the length Hmw2 of the electrode 108 in the WL region WR with respect to the Z direction can be increased more than the length Hmc2 of the electrode 108 in the cell region CR with respect to the Z direction. It is thereby possible to increase the volume of the bonding pad MBw in the WL region WR of the array chip 10 more than the volume of the bonding pad MBc of the cell region CR. For this reason, in the annealing in the bonding process, it is possible to increase the thermal expansion amount of the conductor 108_2 of the electrode 108 in the WL region WR more than the thermal expansion amount of the conductor 108_2 of the electrode 108 in the cell region CR. As a result, in the WL region WR where bonding defects tend to occur due to electro migration, an effective contact area between the conductor 108_2 of the electrode 108 and the conductor 210_2 of the electrode 210 on the circuit chip side can be increased. Therefore, bonding defects can be reduced in the WL region WR.

For example, a pattern of a relatively wide groove, such as an alignment pattern, etc., is formed in the same layer as the electrode 108. In this case, the film thickness of the conductive material to embed the electrode 108 is set to be a sufficient film thickness to embed a wide groove pattern. Therefore, if the depth of the wide groove pattern becomes greater, the film thickness of the conductive material to be deposited increases. In the configuration according to the present embodiment, on the other hand the thickness of the bonding pad MBw in the WL region WR can be selectively increased, without changing the depth of the wide groove pattern. It is thereby possible to suppress an increase in the film thickness of the conductive material to be deposited in order to embed the electrode 108. Therefore, an increase in a cost for manufacturing the semiconductor memory device 1 can be suppressed. Furthermore, with the structure according to the present embodiment, the ratio of the length (Hmc2−Hmc1) of the contact plug VB with respect to the z direction to the length Hmc2 of the electrode 108 in the cell region CR with respect to the Z direction can be equal to or smaller than 40%. In the WL region WR, the ratio of the length (Hmw2−Hmw1) of the contact plug VB with respect to the Z direction to the length Hmw2 of the electrode 108 with respect to the Z direction can be equal to or smaller than 35%. In the circuit chip 20, the ratio of the length (Hd2−Hd1) of the contact plug CB with respect to the Z direction to the length Hd2 of the electrode 210 with respect to the Z direction can be equal to or smaller than 40%. It is thus possible to reduce breaks and defects in the contact plugs VB and CB due to a tensile stress.

Furthermore, with the structure according to the present embodiment, the aspect ratio of the contact plugs VB and CB can be 1.5 or smaller. It is thus possible to reduce breaks and defects in the contact plugs VB and CB due to a tensile stress.

### 2. Second Embodiment

Next, the second embodiment will be described. In the second embodiment, a method of forming a step between the cell region CR and the WL region WR, which differs from that in the first embodiment, is described. Hereinafter, the description will focus mainly on matters different from those of the first embodiment.

### 2.1 Cross-Sectional Structure of Semiconductor Memory Device

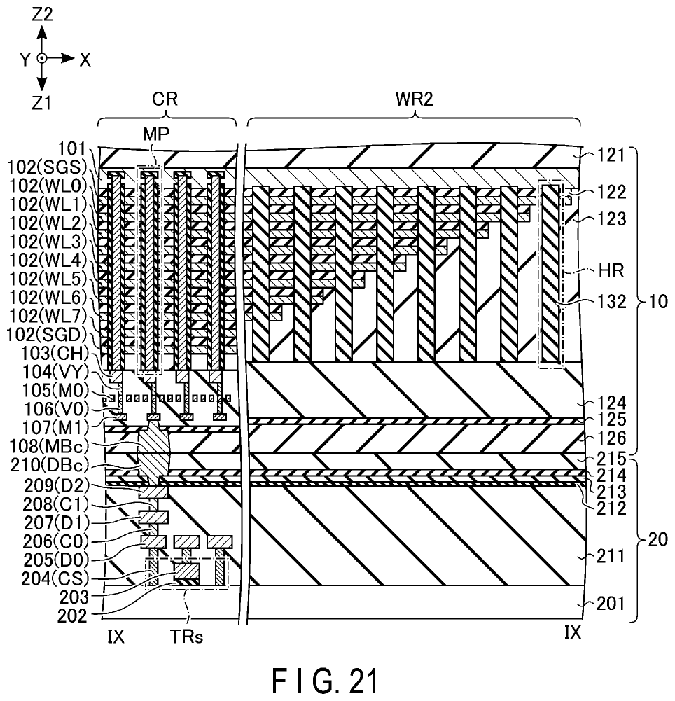

First, a cross-sectional structure of the array chip 10 is described with reference to FIG. 21. FIG. 21 is a cross-sectional view of the semiconductor memory device 1, along line IX-IX of FIG. 5. The semiconductor memory device 1 of the present embodiment differs from the first embodiment in the structure of the dummy pillars HR.

As shown in FIG. 21, the dummy pillars HR in the present embodiment are embedded by the insulator 132. The insulator 132 is for example, silicon oxide. Other structures are the same as those of the first embodiment shown in FIG. 7.

### 2.2 Method of Manufacturing Memory Cell Array and Electrode

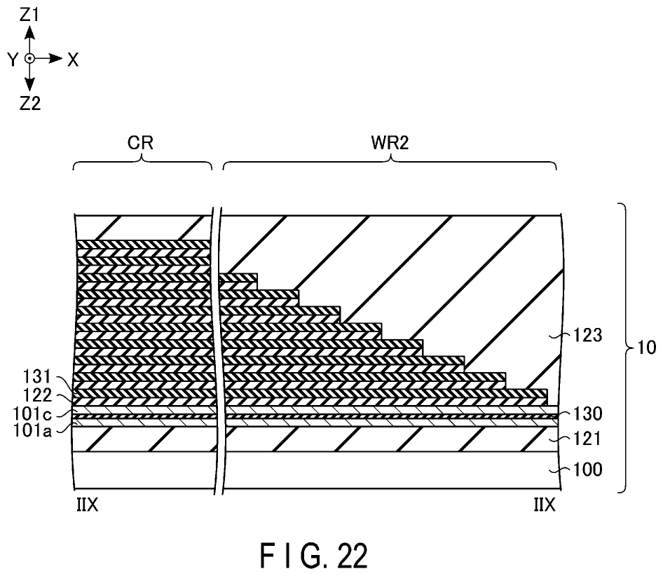

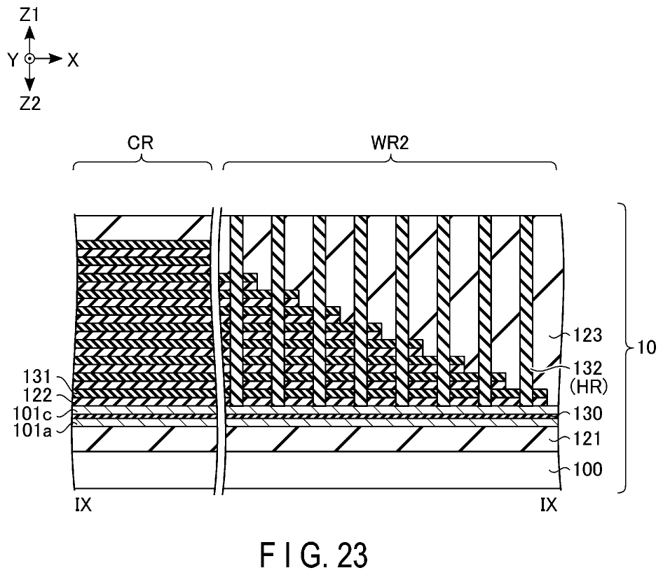

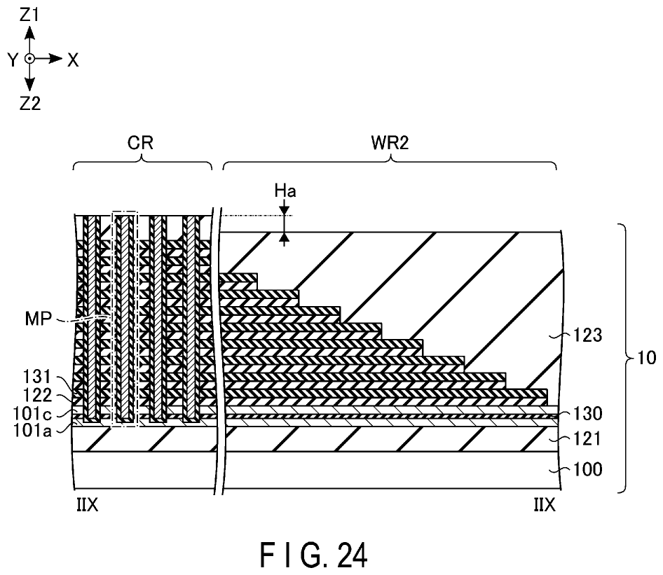

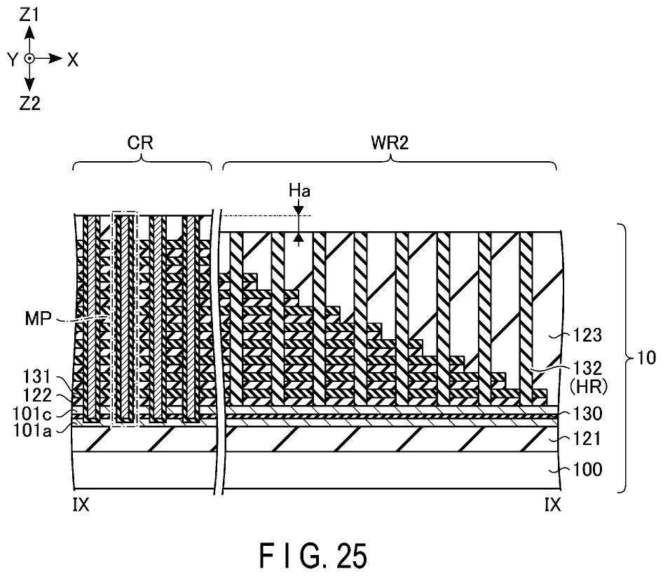

Next, an example of a method of manufacturing the memory cell array 11 and the electrodes 108 is described, with reference to FIGS. 22-25. FIGS. 22 to 25 are cross-sectional views indicating the process of manufacturing the memory cell array 11 and the electrodes 108 of the array chip 10. FIGS. 22 and 24 show examples of cross-sectional structures of the array chip 10 viewed along line IIX-IIX of FIG. 5. FIGS. 23 and 25 show examples of cross-sectional structures of the array chip 10 viewed along line IX-IX of FIG. 5. As shown in FIG. 22, similarly to the description of FIG. 11 of the first embodiment, the insulating layer 123 is deposited so as to cover the entire surface facing in the Z1 direction of the semiconductor substrate 100 after steps of the plurality of insulating layers 122 and the plurality of sacrificial layers 131 are formed. Next, CMP is performed on the insulating layer 123. In the present embodiment, the surface of the insulating layer 123 is flattened. In other words, no step is formed between the cell region CR and the WL region WR. A step similar to the example of the first embodiment shown in FIG. 11 may be formed.

As shown in FIG. 23, the dummy pillars HR are formed in the WL region WR. More specifically, dummy holes corresponding to the dummy pillars HR are formed. Next, the dummy holes are embedded by the insulator 132.

As shown in FIGS. 24 and 25, the memory pillars MP are formed in the cell region CR. At this time, the thermal processing for crystallizing the semiconductor film 143 of the memory pillar MP is performed. The insulating layer 123 and the insulator 132 are thereby contracted in the region other than the cell region CR in which the memory pillars MP are provided. As a result, the step of the height Ha is formed between the cell region CR and the WL region WR.

The process hereinafter is the same as that in the first embodiment.

### 2.3 Advantageous Effects of Second Embodiment

The configuration of the present embodiment can attain the same effect as the first embodiment.

As a method of adjusting a thickness difference between the bonding pad MBw and the bonding pad MBc, the first embodiment and the second embodiment may be combined.

### 3. Third Embodiment

Next, the third embodiment will be described. In the third embodiment, a method of forming a step between the cell region CR and the WL region WR which differs from that in the first embodiment and the second embodiment is described. Hereinafter, the explanation will focus mainly on matters which differ from the first and second embodiments.

### 3.1 Cross-Sectional Structure of Semiconductor Memory Device

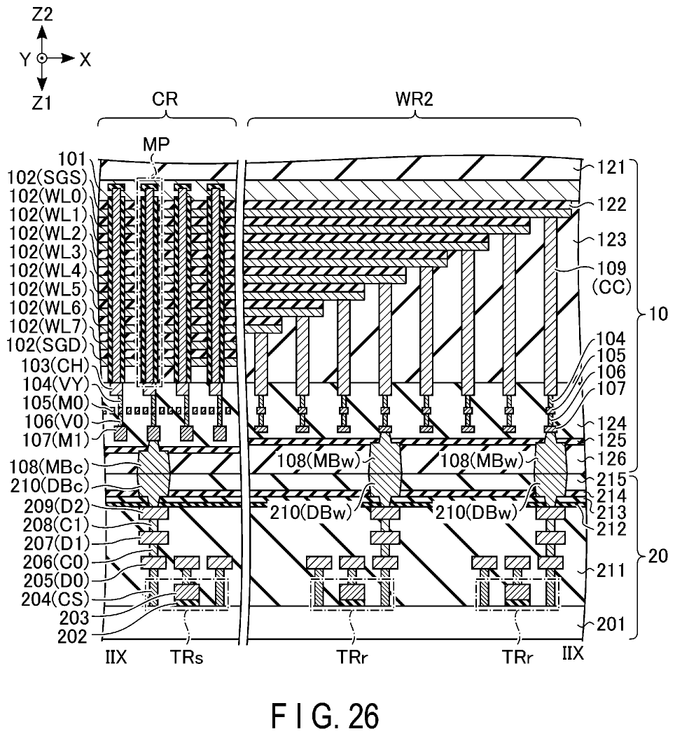

First, a cross-sectional structure of the array chip 10 is described with reference to FIG. 26. FIG. 26 is a cross-sectional view of the semiconductor memory device 1, along line IIX-IIX of FIG. 5. In the semiconductor memory device 1 of the present embodiment, the film thickness of the M1 interconnect layer 107 differs between the cell region CR and the WL region WR.

As shown in FIG. 26, a step is not provided between the cell region CR and the WL region WR in the insulating layer 123 of the present embodiment. For this reason, the height positions of the conductors 104 (contact plug VY), the M0 interconnect layers 105, and the conductors 106 (contact plug V0) are approximately the same between the cell region CR and the WL region WR.

In the present embodiment, the film thickness of the M1 interconnect layer 107 (thickness of the interconnect layer) in the cell region CR is larger than that of the M1 interconnect layer 107 in the WL region WR. For this reason, the height position of the surface facing in the Z1 direction of the interconnect layer 107 in the cell region CR is lower than that in the WL region WR. The step between the cell region CR and the WL region WR is thereby created. Other structures are the same as those of the first embodiment shown in FIG. 6.

### 3.2 Cross-Sectional Structure of M1 Interconnect Layer and Bonding Pad

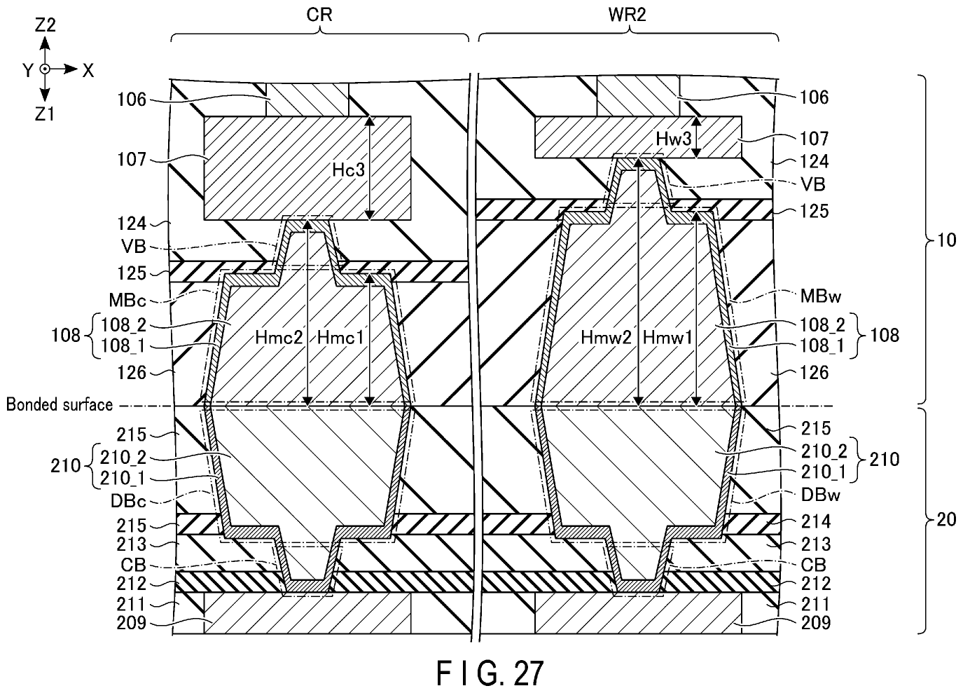

Next, an example of a cross-sectional structure of the M1 interconnect layer 107 and the bonding pad BP is described with reference to FIG. 27. FIG. 27 is a cross-sectional view of an example of the bonding pad BP and corresponds to the example of the first embodiment shown in FIG. 8. The example of FIG. 27 shows a region including the M1 interconnect layer 107.

As shown in FIG. 27, the structure of the electrodes 108 and the electrodes 210 are the same as those of the first embodiment shown in FIG. 8.

The height position of the surface facing in the Z2 direction of the M1 interconnect layer 107 in the present embodiment is approximately the same between the cell region CR and the WL region WR. Suppose the length of the M1 interconnect layer 107 in the cell region CR with respect to the Z direction is Hc3. Suppose the length of the M1 interconnect layer 107 in the WL region WR with respect to the Z direction is Hw3. The length Hc3 and the length Hw3 are in the relationship of Hc3>Hw3. The difference (Hmw1−Hmc1) between the length of the bonding pad MBw with respect to the Z direction and the length Hmc1 of the bonding pad MBc with respect to the Z direction is based on the difference (Hc3−Hw3) in the length of the M1 interconnect layer 107 (thickness of the interconnect layer). Therefore, the bonding pad MB and the M1 interconnect layer 107 is in the relationship of Hmw1−Hmc1=Hc3−Hw3.

### 3.3 Method of Manufacturing Memory Cell Array and Electrode

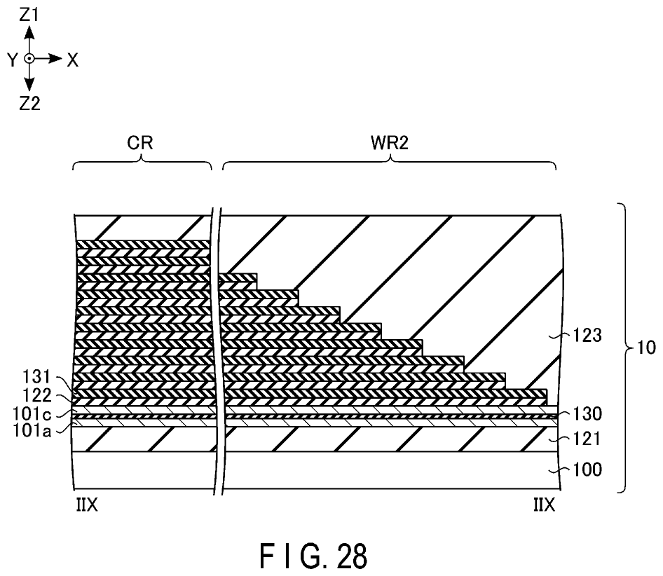

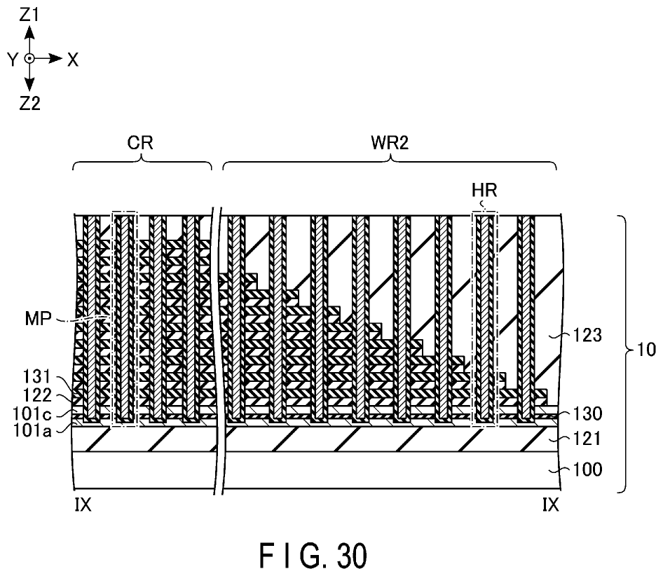

Next, an example of a method of manufacturing the memory cell array 11 and the electrodes 108 is described, with reference to FIGS. 28-33. FIGS. 28 to 33 are cross-sectional views indicating the process of manufacturing the memory cell array 11 and the electrodes 108 of the array chip 10. FIGS. 28, 29, and 31-33 show examples of cross-sectional structures of the array chip 10 viewed along line IIX-IIX of FIG. 5. FIG. 30 shows an example of a cross-sectional structure of the array chip 10 viewed along line IX-IX of FIG. 5.

As shown in FIG. 28, similarly to the description of FIG. 22 of the second embodiment, the insulating layer 123 is deposited so as to cover the entire surface facing in the Z1 direction of the semiconductor substrate 100 after steps of the plurality of insulating layers 122 and the plurality of sacrificial layers 131 are formed. Next, CMP is performed on the insulating layer 123. In the present embodiment, the surface of the insulating layer 123 is flattened. In other words, no step is formed between the cell region CR and the WL region WR. A step similar to the example of the first embodiment shown in FIG. 11 may be formed.

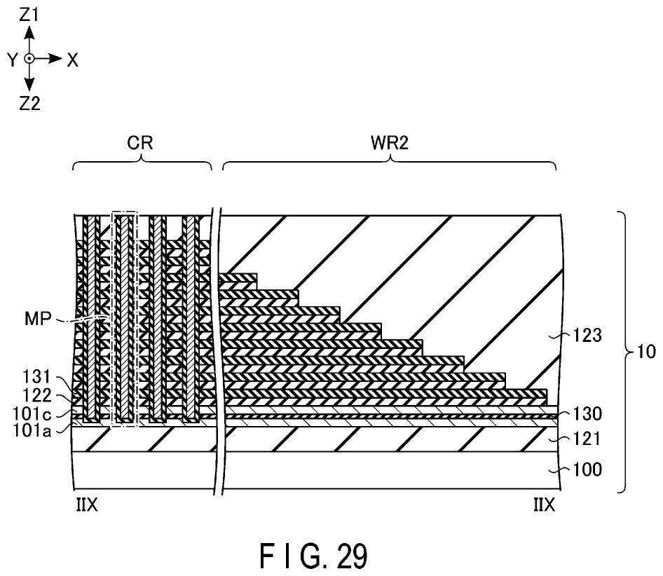

As shown in FIGS. 29 and 30, the memory pillars MP and the dummy pillars HR are formed through procedures similar to those of the first embodiment explained using FIGS. 12 and 13. Unlike the first embodiment, a step is not formed between the cell region CR and the WL region WR.

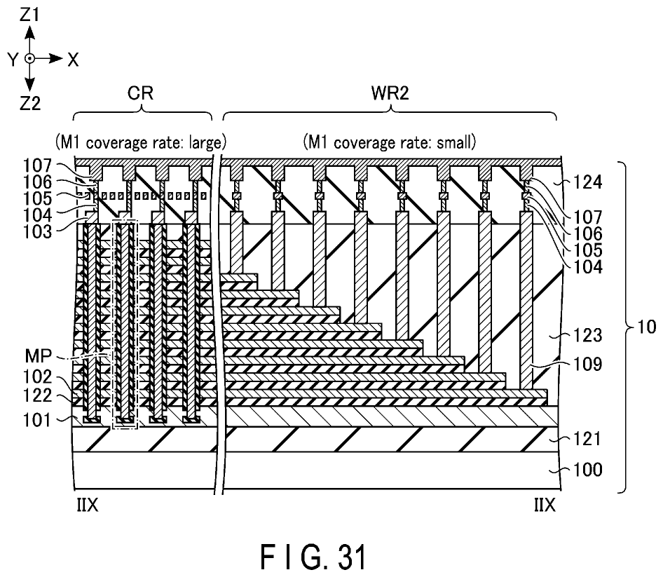

As shown in FIG. 31, the conductors 103 and 109, the conductors 104, the M0 interconnect layers 105, and the conductors 106 are formed. Next, the M1 interconnect layers 107 are formed. At this time, the coverage rate of the M1 interconnect layers 107 in the WL region WR is made smaller than that in the cell region CR. The coverage rate is a ratio of an area size of the patterns arranged in a region. More specifically, patterns corresponding to the M1 interconnect layers 107 are first formed. If the conductors 106 and the M1 interconnect layers 107 are formed in a batch by the dual damascene method, patterns corresponding to the conductors 106 and the M1 interconnect layers 107 are formed. Next, a conductive material is deposited, and the above patterns are embedded in the conductive material. At this stage, a step is not formed between the cell region CR and the WL region WR.

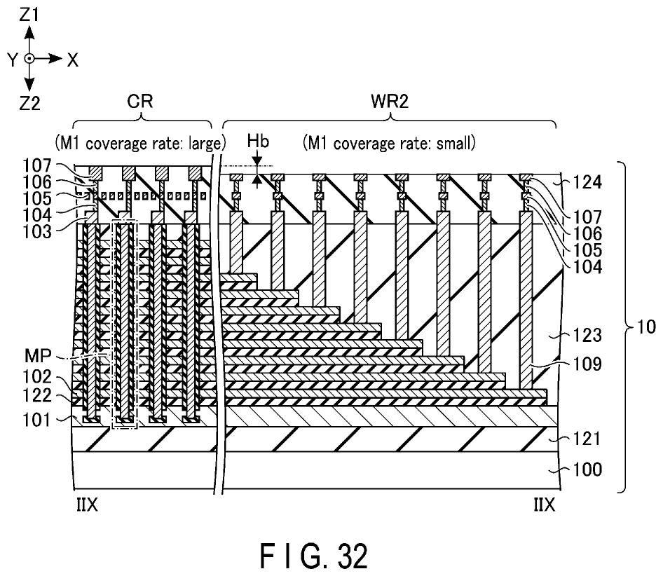

As shown in FIG. 32, residual conductive material on the insulating layer 124 is removed by CMP. At this time, erosion occurs in the WL region WR having a lower coverage rate, and the entire region including the insulating layer 124 is polished. As a result, a step of a height Hb is created between the cell region CR and the WL region WR. The M1 interconnect layers 107 having a difference film thickness each other in the cell region CR and the WL region WR are formed.

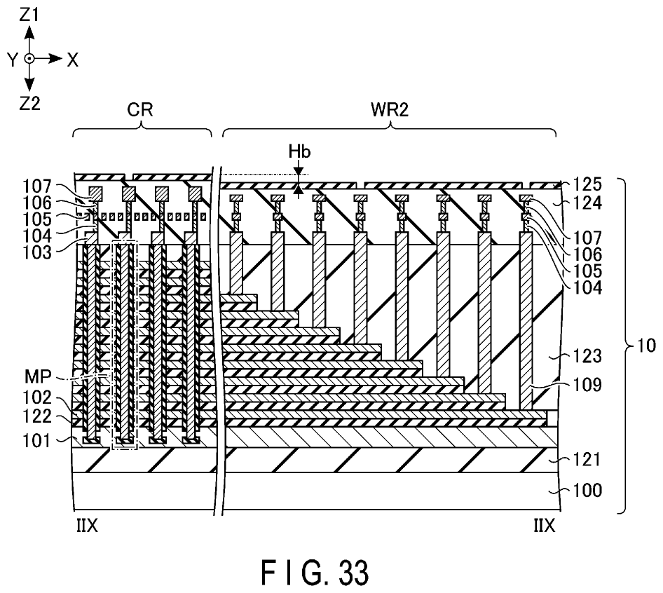

As shown in FIG. 33, the insulating layers 124 and 125 are deposited. Next, a mask pattern for forming the contact plugs VB is formed by processing the insulating layer 125. The process hereinafter is the same as that in the first embodiment.

In the present embodiment, the example where the film thickness of the M1 interconnect layers 107 differs between the cell region CR and the WL region WR is described; however, the present embodiment is not limited to this example. For example, the film thickness of the M0 interconnect layers 105 may differ between the cell region CR and the WL region WR, or the film thickness of both the M0 interconnect layers 105 and the M1 interconnect layers 107 may differ between the cell region CR and the WL region WR.

### 3.4 Advantageous Effects of Third Embodiment

The configuration of the present embodiment can attain the same effect as the first embodiment.

As a method of adjusting a thickness difference between the bonding pad MBw and the bonding pad MBc, the first through third embodiments may be combined.

### 4. Modification

According to the above embodiment, a semiconductor memory device includes a first chip (10) and a second chip (20). The first chip includes a plurality of first interconnect layers (WL) stacked apart from each other in a first direction (Z direction), a memory pillar (MP) extending in the first direction and passing through the plurality of first interconnect layers, a second interconnect layer (BL) electrically coupled to the memory pillar, a first electrode (108 in WR) electrically coupled to any one of the plurality of first interconnect layers, and a second electrode (108 in CR) electrically coupled to the second interconnect layer. The second chip includes a third electrode (210 in WR) bonded to the first electrode, and a fourth electrode (210 in CR) bonded to the second electrode. A length of the first electrode in the first direction (Hmw2) is larger than a length of the second electrode in the first direction (Hmc2).

By applying the above embodiments, defects in bonding in the semiconductor memory device 1 can be reduced.

The embodiments are not limited to the above-described aspects, but can be modified in various ways.

The state of being “coupled” in the foregoing embodiments includes a state of being coupled with something else indirectly interposed via some element, such as a transistor or a resistor.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first chip including:
a plurality of first interconnect layers stacked apart from each other in a first direction;
a memory pillar extending in the first direction and passing through the plurality of first interconnect layers;
a second interconnect layer electrically coupled to the memory pillar;
a first electrode electrically coupled to any one of the plurality of first interconnect layers; and
a second electrode electrically coupled to the second interconnect layer; and
a second chip including:
a third electrode bonded to the first electrode; and
a fourth electrode bonded to the second electrode, wherein
a length of the first electrode in the first direction is larger than a length of the second electrode in the first direction.

2. The semiconductor memory device according to claim 1, wherein
the first electrode includes:
a first pad a lower surface of the first pad being in contact with the third electrode; and
a first contact plug that is in contact with an upper surface of the first pad the upper surface facing the lower surface,
the second electrode includes:
a second pad a lower surface of the second pad being in contact with the fourth electrode; and
a second contact plug that is in contact with an upper surface of the second pad the upper surface facing the lower surface, and
a length of the first pad in the first direction is larger than a length of the second pad in the first direction.

3. The semiconductor memory device according to claim 2, wherein
a ratio of a length of the second contact plug in the first direction to the length of the second electrode is equal to or smaller than 40%.

4. The semiconductor memory device according to claim 2, wherein
a ratio of a length of the first contact plug in the first direction to the length of the first electrode is equal to or smaller than 35%.

5. The semiconductor memory device according to claim 2, wherein
an aspect ratio of each of the first contact plug and the second contact plug is equal to or smaller than 1.5.

6. The semiconductor memory device according to claim 1, wherein
the first chip includes:
a first region in which a first conductor extending in the first direction and coupled to one of the plurality of first interconnect layers is provided; and
a second region in which the memory pillar is arranged,
the first electrode is provided in the first region and electrically coupled to one of the plurality of first interconnect layers via the first conductor, and
the second electrode is provided in the second region.

7. The semiconductor memory device according to claim 1, wherein
a first surface of the first chip is bonded to the second chip, and
a lower surface of the first electrode and a lower surface of the second electrode are arranged in the first surface.

8. The semiconductor memory device according to claim 2, wherein
a length of the first contact plug in the first direction is approximately same as a length of the second contact plug in the first direction.

9. The semiconductor memory device according to claim 2, wherein
the first chip further includes:
a first insulating layer provided below the plurality of first interconnect layers;
a second insulating layer provided below the first insulating layer and made of a material differing from that of the first insulating layer; and
a third insulating layer provided below the second insulating layer and being in contact with the second chip,
the first contact plug and the second contact plug are provided within the first insulating layer,
the first pad and the second pad are provided in a same layer as the third insulating layer, and
the upper surface of the first pad and the upper surface of the second pad are in contact with the second insulating layer.

10. The semiconductor memory device according to claim 9, wherein
the second insulating layer is one of SiN and SiCN.

11. The semiconductor memory device according to claim 9, wherein
a first position of the second insulating layer being in contact with the first electrode differs from a second position of the second insulating layer being in contact with the second electrode in the first direction.

12. The semiconductor memory device according to claim 9, wherein
a first film thickness of the third insulating layer being in contact with the first electrode is greater than a second film thickness of the third insulating layer being in contact with the second electrode.

13. The semiconductor memory device according to claim 2, wherein
the first chip further includes:
a third interconnect layer electrically coupled to one of the plurality of first interconnect layers and being in contact with the first contact plug; and
a fourth interconnect layer electrically coupled to the second interconnect layer and being in contact with the second contact plug, and
a position of the third interconnect layer in the first direction differs from a position of the fourth interconnect layer in the first direction.

14. The semiconductor memory device according to claim 13, wherein
a film thickness of the third interconnect layer is approximately same as a film thickness of the fourth interconnect layer.

15. The semiconductor memory device according to claim 2, wherein
the first chip further includes:
a third interconnect layer electrically coupled to one of the plurality of first interconnect layers and being in contact with the first contact plug; and
a fourth interconnect layer electrically coupled to the second interconnect layer and being in contact with the second contact plug, and
a film thickness of the third interconnect layer is smaller than a film thickness of the fourth interconnect layer.

16. The semiconductor memory device according to claim 2, wherein
the third electrode includes:
a third pad an upper surface of the third pad being in contact with the first electrode; and
a third contact plug that is in contact with a lower surface of the third pad the lower surface facing the upper surface, and
a ratio of a length of the third contact plug in the first direction to a length of the third electrode in the first direction is equal to or smaller than 40%.

17. The semiconductor memory device according to claim 16, wherein
an aspect ratio of the third contact plug is equal to or smaller than 1.5.

18. The semiconductor memory device according to claim 1, wherein
the second chip further includes a row decoder and a sense amplifier,
the third electrode is electrically coupled to the row decoder, and
the fourth electrode is electrically coupled to the sense amplifier.

19. The semiconductor memory device according to claim 2, wherein
the first electrode includes:
a second conductor provided in a side surface and the upper surface of the first pad and a side surface and an upper surface of the first contact plug; and
a third conductor being in contact with the second conductor and provided in the second conductor.

20. The semiconductor memory device according to claim 1, wherein
the memory pillar includes:
a semiconductor layer extending in the first direction; and
a charge storage film provided between the plurality of first interconnect layers and the semiconductor layer, and
the second interconnect layer is electrically coupled to the semiconductor layer.
